(19) United States
(12) Patent Application Publication
(10) Pub. No.: US 2025/0300104 A1
(43) Pub. Date: Sep. 25, 2025

(54) INTEGRATED DEVICE COMPRISING METALLIZATION PORTION WITH STEP PAD INTERCONNECTS

(71) Applicant: QUALCOMM Incorporated, San Diego, CA (US)

(72) Inventors: Yangyang SUN, San Diego, CA (US); Xuefeng ZHANG, San Diego, CA (US); Jun CHEN, San Diego, CA (US)

(21) Appl. No.: 18/611,385

(22) Filed: Mar. 20, 2024

(51) Int. Cl. H01L 23/00; H01L 23/48; H01L 23/522; H01L 23/528

(52) U.S. Cl. CPC H01L 24/05; H01L 23/481; H01L 23/5226; H01L 23/528; H01L 24/16; H01L 24/32; H01L 24/73; H01L 2224/02373; H01L 2224/0401; H01L 2224/05582; H01L 2224/16145; H01L 2224/32145; H01L 2224/73204

(57) ABSTRACT

An integrated device comprising a die substrate; a die interconnection coupled to the die substrate; an encapsulation layer coupled to a side surface of the die substrate and a side surface of the die interconnection; a plurality of pad interconnects coupled to the die interconnection; a passivation layer coupled to the die interconnection; and a plurality of metallization interconnects, wherein one or more metallization interconnects from the plurality of metallization interconnects is coupled to one or more pad interconnects from the plurality of pad interconnects, wherein the plurality of metallization interconnects comprise a first step pad interconnect structure.

### FIELD

Various features relate to integrated devices.

### BACKGROUND

An integrated device is configured to perform various electrical functions. The performance of the integrated device and how it performs these various electrical functions will depend on how interconnects are arranged. There is an ongoing need to improve the performance of an integrated device while also reducing the overall form factor of the integrated device.

### SUMMARY

Various features relate to integrated devices.

One example provides an integrated device comprising a die substrate; a die interconnection coupled to the die substrate; an encapsulation layer coupled to a side surface of the die substrate and a side surface of the die interconnection; a plurality of pad interconnects coupled to the die interconnection; a passivation layer coupled to the die interconnection; and a plurality of metallization interconnects, wherein one or more metallization interconnects from the plurality of metallization interconnects is coupled to one or more pad interconnects from the plurality of pad interconnects, wherein the plurality of metallization interconnects comprise a first step pad interconnect structure.

Another example provides a package comprising a first integrated device comprising a first die substrate; a first die interconnection coupled to the first die substrate; a first encapsulation layer coupled to a side surface of the first die substrate and a side surface of the first die interconnection; a first plurality of pad interconnects coupled to the first die interconnection; a passivation layer coupled to the first die interconnection; a first plurality of metallization interconnects, wherein one or more metallization interconnects from the first plurality of metallization interconnects is coupled to one or more pad interconnects from the first plurality of pad interconnects, wherein the first plurality of metallization interconnects comprise a first step pad interconnect structure; and a second integrated device coupled to the first integrated device through at least a first plurality of solder interconnects.

Another example provides a device comprising a die substrate; a die interconnection coupled to the die substrate; an encapsulation layer coupled to a side surface of the die substrate and a side surface of the die interconnection; a plurality of pad interconnects coupled to the die interconnection; a passivation layer coupled to the die interconnection; and a plurality of metallization interconnects, wherein one or more metallization interconnects from the plurality of metallization interconnects is coupled to one or more pad interconnects from the plurality of pad interconnects, wherein the plurality of metallization interconnects comprise a first step pad interconnect structure.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary integrated device with a step pad interconnect.

FIG. 2 illustrates a cross sectional profile view of an exemplary integrated device with a step pad interconnect.

FIG. 3 illustrates a cross sectional profile view of an exemplary integrated device with a step pad interconnect.

FIG. 4 illustrates a cross sectional plan view of an exemplary integrated device.

FIG. 5 illustrates a cross sectional plan view of an exemplary integrated device with a step pad interconnect.

FIG. 6 illustrates an exemplary view of step pad interconnects.

FIG. 7 illustrates a cross sectional profile view of an exemplary package that includes two integrated devices.

FIG. 8 illustrates a cross sectional profile view of an exemplary package that includes two integrated devices.

FIG. 9 illustrates a cross sectional profile view of an exemplary package that includes two integrated devices.

FIG. 10 illustrates a cross sectional profile view of an exemplary package that includes two integrated devices.

FIG. 11 illustrates a cross sectional profile view of an exemplary package that includes two integrated devices.

FIG. 12 illustrates a cross sectional profile view of an exemplary package that includes two integrated devices.

FIGS. 13A-13G illustrate an exemplary sequence for fabricating an integrated device.

FIG. 14 illustrates an exemplary flow diagram of a method for fabricating an integrated device.

FIG. 15 illustrates a cross sectional profile view of an exemplary integrated device.

FIG. 16 illustrates a cross sectional profile view of an exemplary package comprising several integrated devices.

FIGS. 17A-17C illustrate an exemplary sequence for fabricating a package comprising several integrated devices.

FIG. 18 illustrates an exemplary flow diagram of a method for fabricating a package comprising several integrated devices.

FIG. 19 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes an integrated device comprising a die substrate; a die interconnection coupled to the die substrate; an encapsulation layer coupled to a side surface of the die substrate and a side surface of the die interconnection; a plurality of pad interconnects coupled to the die interconnection; a passivation layer coupled to the die interconnection; and a plurality of metallization interconnects, wherein one or more metallization interconnects from the plurality of metallization interconnects is coupled to one or more pad interconnects from the plurality of pad interconnects, wherein the plurality of metallization interconnects comprise a first step pad interconnect structure. In some implementations, the integrated device provides a reduced and/or minimized number of metal layers for metallization interconnects, in a compact form factor, while also providing high density interconnects, which can help provide improved performance for the integrated device.

### Exemplary Integrated Devices Comprising Step Pad Interconnects

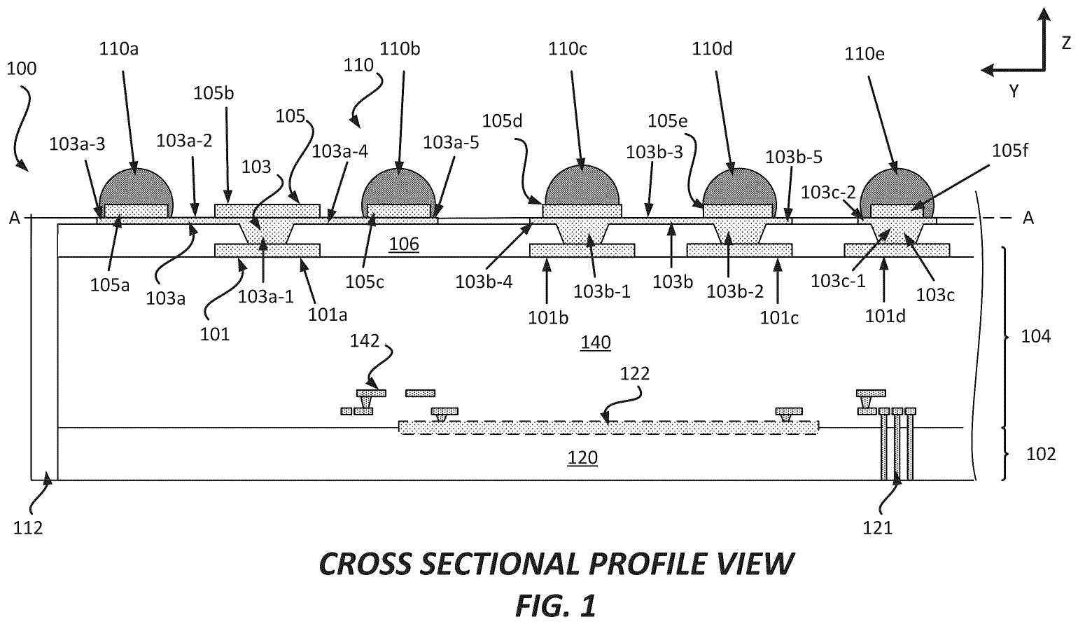

FIG. 1 illustrates a cross sectional profile view of an integrated device 100. The integrated device 100 includes at least one step pad interconnect. The integrated device 100 includes a die substrate base 102 and a die interconnection 104. The die substrate base 102 includes a die substrate 120, an active region 122 and a plurality of through substrate vias 121. The active region 122 and the plurality of through substrate vias 121 may be considered part of the die substrate 120. The plurality of through substrate vias 121 may include plated through holes. The active region 122 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 122 of the die substrate 120.

The die substrate 120 may include silicon (Si). The die substrate 120 may comprise a bulk silicon. The bulk silicon may include a monolithic silicon. The plurality of through substrate vias 121 may extend through the die substrate 120. Different implementations may have different thicknesses for the die substrate 120.

The die interconnection 104 includes at least one dielectric layer 140 and at least one die metallization layer (e.g., die metal 0, die metal 1) with a plurality of die interconnects 142. The plurality of die interconnects 142 may be formed in and between metallization layers of the die interconnection 104. The die interconnection 104 is coupled to the die substrate base 102. The plurality of die interconnects 142 are coupled to the active region 122 of the die substrate base 102. The plurality of die interconnects 142 may be coupled to the plurality of through substrate vias 121. The die interconnection 104 may also include a plurality of pad interconnects 101 and a passivation layer 106. In some implementations, a back end of line (BEOL) process may be used to fabricate the die interconnection 104. The die interconnection 104 may be a BEOL die interconnection. The die interconnection 104 may be an on-die interconnection.

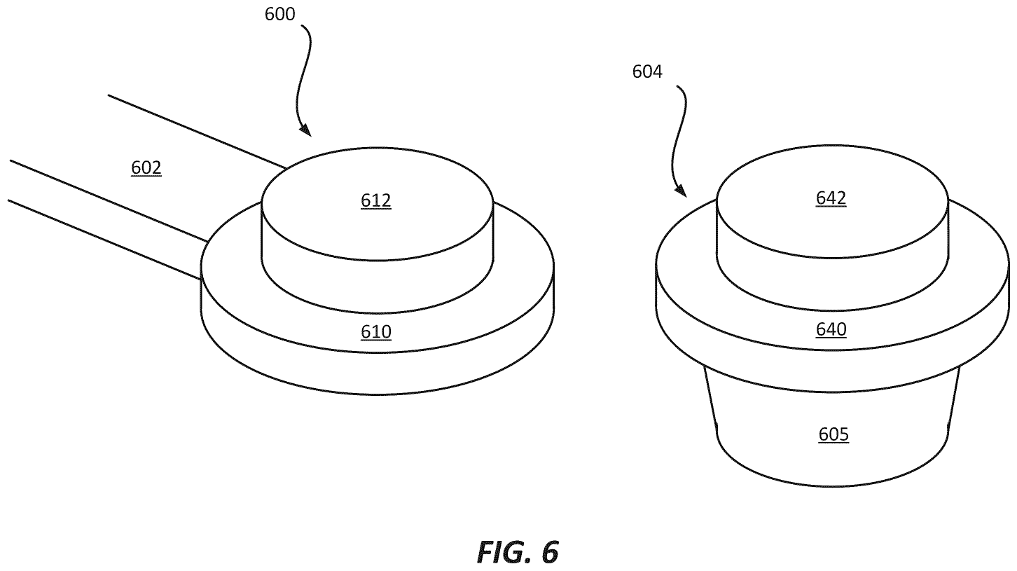

The integrated device 100 includes a passivation layer 106, a plurality of pad interconnects 101, a plurality of metallization interconnects 103, a plurality of metallization interconnects 105, a plurality of solder interconnects 110, an encapsulation layer 112. The passivation layer 106 may be provided on the die interconnection 104. The plurality of solder interconnects 110 may be a plurality of solder bumps (e.g., solder bump interconnects). As will be further described below, some of the metallization interconnects from the plurality of metallization interconnects 103 and the plurality of metallization interconnects 105, may be configured as step pad interconnects (e.g., step pad metallization interconnects). In some implementations, the step pad interconnects are landing step pad interconnects. Landing step pad interconnects may be interconnects that are configured to be coupled to solder interconnects. Examples of step pad interconnects are illustrated and described further below in at least FIG. 6.

The configuration of using metallization interconnects from the plurality of metallization interconnects 103 and metallization interconnects from the plurality of metallization interconnects 105 to form the step pad interconnects, helps provide additional surface area (e.g., wall surface area, Z-direction surface) for solder to couple to, and is thus less likely to spread out and (unintentionally) couple to other nearby pad interconnects. Therefore, the use of the step pad interconnects helps provide tighter pitch between interconnects (e.g., step pad interconnects, solder bump interconnects), since the additional surface area help prevent solder from spreading out (e.g., away from the step pad interconnects), which allows the step pad interconnects to be closer to each other. Thus, the step pad interconnects may help provide higher density interconnects (e.g., more electrical paths for a given area and/or region), which can help improve the overall performance of the integrated device. In some implementations, the pitch between adjacent and/or neighboring step pad interconnects may be in a range of about 10-50 micrometers.

The plurality of pad interconnects 101 may include a pad interconnect 101a, a pad interconnect 101b, a pad interconnect 101c and a pad interconnect 101d. The plurality of metallization interconnects 103 may include a metallization interconnect 103a, a metallization interconnect 103b and a metallization interconnect 103c. The plurality of metallization interconnects 105 may include a pad metallization interconnect 105a, a pad metallization interconnect 105b, a pad metallization interconnect 105c, a pad metallization interconnect 105d, a pad metallization interconnect 105e, and a pad metallization interconnect 105f. In some implementations, a back end of line (BEOL) process may be used to fabricate the passivation layer 106, the plurality of pad interconnects 101, the plurality of metallization interconnects 103, and the plurality of metallization interconnects 105.

The plurality of pad interconnects 101 may be coupled to the plurality of die interconnects 142. The plurality of pad interconnects 101 may include Aluminum (Al). The plurality of die interconnects 142 may include copper (Cu). The plurality of die interconnects 142 may include a different material from the plurality of pad interconnects 101. The passivation layer 106 may be located over the at least one dielectric layer 140. The passivation layer 106 may be coupled to and touch a top surface of the at least one dielectric layer 140. The passivation layer 106 may be located over at least part of the plurality of pad interconnects 101. The passivation layer 106 may include a material that is different from the at least one dielectric layer 140.

The plurality of metallization interconnects 103 may include copper (Cu), Nickel (Ni), Gold (Au), Platinum (Pt), Tin-Silver (Tn/Ag), and/or combinations thereof. The metallization interconnect 103a may be coupled to and touch the pad interconnect 101a. The metallization interconnect 103a may include a via metallization interconnect 103a-1, a trace metallization interconnect 103a-2, a first pad metallization interconnect 103a-3, a second pad metallization interconnect 103a-4 and a third pad metallization interconnect 103a-5. The metallization interconnect 103b may be coupled to and touch the pad interconnect 101b and the pad interconnect 101c. The metallization interconnect 103b may include a first via metallization interconnect 103b-1, a second via interconnect 103b-2, a trace metallization interconnect 103b-3, a first pad metallization interconnect 103b-4, and a second pad metallization interconnect 103b-5. The metallization interconnect 103c may be coupled to and touch the pad interconnect 101d. The metallization interconnect 103c may include a via metallization interconnect 103c-1 and a pad metallization interconnect 103c-2. The first pad metallization interconnect 103a-3, the second pad metallization interconnect 103a-4, the third pad metallization interconnect 103a-5, the trace metallization interconnect 103b-3, the first pad metallization interconnect 103b-4, the second pad metallization interconnect 103b-5 and the pad metallization interconnect 103c-2 may be located on the same metal layer.

The plurality of metallization interconnects 105 may be coupled to and touch the plurality of metallization interconnects 103. The plurality of metallization interconnects 105 include pad metallization interconnects, such as a pad metallization interconnect 105a, a pad metallization interconnect 105b, a pad metallization interconnect 105c, a pad metallization interconnect 105d, a pad metallization interconnect 105e and a pad metallization interconnect 105f. The pad metallization interconnect 105a may be coupled to and touch the first pad metallization interconnect 103a-3. The pad metallization interconnect 105b may be coupled to and touch the second pad metallization interconnect 103a-4. The pad metallization interconnect 105c may be coupled to and touch the third pad metallization interconnect 103a-5. The pad metallization interconnect 105d may be coupled to and touch the first pad metallization interconnect 103b-4. The pad metallization interconnect 105e may be coupled to and touch the second pad metallization interconnect 103b-5. The pad metallization interconnect 105f may be coupled to and touch the pad metallization interconnect 103c-2. The pad metallization interconnect 105a may vertically overlap and/or vertically align with the first pad metallization interconnect 103a-3. The pad metallization interconnect 105b may vertically overlap and/or vertically align with the second pad metallization interconnect 103a-4. The pad metallization interconnect 105c may vertically overlap and/or vertically align with the third pad metallization interconnect 103a-5. The pad metallization interconnect 105d may vertically overlap and/or vertically align with the first pad metallization interconnect 103b-4. The pad metallization interconnect 105e may vertically overlap and/or vertically align with the second pad metallization interconnect 103b-5. The pad metallization interconnect 105f may vertically overlap and/or vertically align with the pad metallization interconnect 103c-2. A first pad metallization interconnect that vertically aligns with a second pad metallization interconnect may mean that a center of the first pad metallization interconnect may vertically align with a center of the second pad metallization interconnect. The plurality of metallization interconnects 105 may be located over the plurality of metallization interconnects 103. More detailed examples of how pad metallization interconnects may vertically overlap, and/or vertically align and/or how they may be coupled and touch are illustrated and described below in at least FIG. 6. The plurality of metallization interconnects 105 may include copper (Cu), Nickel (Ni), Gold (Au), Platinum (Pt), Tin-Silver (Tn/Ag), and/or combinations thereof.

In some implementations, a combination of the metallization interconnect 105a and a portion of the metallization interconnect 103a may be configured as a step pad interconnect, such as the step pad interconnect 600 described and illustrated in FIG. 6. In some implementations, a combination of the metallization interconnect 105b and a portion of the metallization interconnect 103a may be configured as a step pad interconnect, such as the step pad interconnect 600 and/or the step pad interconnect 604 described and illustrated in FIG. 6. In some implementations, a combination of the metallization interconnect 105c and a portion of the metallization interconnect 103a may be configured as a step pad interconnect, such as the step pad interconnect 600 described and illustrated in FIG. 6. In some implementations, a combination of the metallization interconnect 105d and a portion of the metallization interconnect 103b may be configured as a step pad interconnect, such as the step pad interconnect 600 and/or the step pad interconnect 604 described and illustrated in FIG. 6. In some implementations, a combination of the pad metallization interconnect 105e and a portion of the metallization interconnect 103b may be configured as a step pad interconnect, such as the step pad interconnect 600 and/or the step pad interconnect 604 described and illustrated in FIG. 6. In some implementations, a combination of the metallization interconnect 105f and a portion of the metallization interconnect 103c may be configured as a step pad interconnect, such as the step pad interconnect 600 and/or the step pad interconnect 604 described and illustrated in FIG. 6.

The encapsulation layer 112 may laterally surround at least part of the plurality of metallization interconnects 103. The encapsulation layer 112 is configured to provide a protection layer, a structural layer and/or layer on which additional metallization interconnects may be formed. The encapsulation layer 112 may be located over the passivation layer 106. The encapsulation layer 112 may include a different material from the passivation layer 106. The encapsulation layer 112 may include a mold, a resin and/or an epoxy. The encapsulation layer 112 may be a means for encapsulation. The encapsulation layer 112 may be provided by using a compression and transfer molding process, a sheet molding process, or a liquid molding process. The encapsulation layer 112 may also be coupled to a side of the die substrate base 102 and/or the die interconnection 104. For example, the encapsulation layer 112 may be coupled to and touch a side wall of the at least one dielectric layer 140 and/or a side wall of the die substrate 120. The encapsulation layer 112 may be located laterally to part of the step pad interconnects. For example, the encapsulation layer 112 may be located laterally to a bottom part of the step pad interconnects (e.g., located laterally to the metallization interconnects 105).

The plurality of solder interconnects 110 are coupled to and touch the plurality of metallization interconnects 105. The plurality of solder interconnects 110 may be a plurality of solder bumps (e.g., solder bump interconnects). The solder interconnect 110a may be coupled to and touch the pad metallization interconnect 105a. The solder interconnect 110a may be coupled to and touch the pad metallization interconnect 105a and a portion of the metallization interconnect 103a (e.g., first pad metallization interconnect 103a-3). The pad metallization interconnect 105a and the first pad metallization interconnect 103a-3 may define a step pad interconnect (e.g., step pad interconnect structure). The solder interconnect 110b may be coupled to and touch the pad metallization interconnect 105c. The solder interconnect 110b may be coupled to and touch the pad metallization interconnect 105c and a portion of the metallization interconnect 103a (e.g., third pad metallization interconnect 103a-5). The pad metallization interconnect 105c and the third pad metallization interconnect 103a-5 may define a step pad interconnect (e.g., step pad interconnect structure). The solder interconnect 110c may be coupled to and touch the pad metallization interconnect 105d. The solder interconnect 110c may be coupled to and touch the pad metallization interconnect 105d and a portion of the metallization interconnect 103b (e.g., first pad metallization interconnect 103b-4). The pad metallization interconnect 105d and the first pad metallization interconnect 103b-4 may define a step pad interconnect (e.g., step pad interconnect structure). The solder interconnect 110d may be coupled to and touch the pad metallization interconnect 105e. The solder interconnect 110d may be coupled to and touch the pad metallization interconnect 105e and a portion of the metallization interconnect 103b (e.g., second pad metallization interconnect 103b-5). The pad metallization interconnect 105e and the second pad metallization interconnect 103b-5 may define a step pad interconnect (e.g., step pad interconnect structure). The solder interconnect 110e may be coupled to and touch the pad metallization interconnect 105f. The solder interconnect 110e may be coupled to and touch the pad metallization interconnect 105f and a portion of the metallization interconnect 103c (e.g., first pad metallization interconnect 103c-2). The pad metallization interconnect 105f and the first pad metallization interconnect 103c-2 may define a step pad interconnect (e.g., step pad interconnect structure).

FIG. 1 illustrates that the plurality of solder interconnects 110 are coupled to and touch step pad interconnects. The solder interconnect 110b may be coupled to and touch the metallization interconnect 105c. The solder interconnect 110b may be coupled to and touch the metallization interconnect 105c and a portion of the metallization interconnect 103a. The solder interconnect 110c may be coupled to and touch the pad metallization interconnect 105d. The solder interconnect 110c may be coupled to and touch the pad metallization interconnect 105d and a portion of the metallization interconnect 103b. The solder interconnect 110d may be coupled to and touch the pad metallization interconnect 105e. The solder interconnect 110d may be coupled to and touch the pad metallization interconnect 105e and a portion of the metallization interconnect 103b. The solder interconnect 110e may be coupled to and touch the metallization interconnect 105f. The solder interconnect 110e may be coupled to and touch the metallization interconnect 105f and a portion of the metallization interconnect 103c. The solder interconnect 110c may vertically overlap and/or vertically align with the pad interconnect 101b. The pad metallization interconnect 105d may vertically overlap and/or vertically align with the pad interconnect 101b. The solder interconnect 110d may vertically overlap and/or vertically align with the pad interconnect 101c. The pad metallization interconnect 105e may vertically overlap and/or vertically align with the pad interconnect 101c. The solder interconnect 110e may vertically overlap and/or vertically align with the pad interconnect 101d. The pad metallization interconnect 105f may vertically overlap and/or vertically align with the pad interconnect 101d. A first pad interconnect that vertically aligns with a second pad interconnect may mean that a center of the first pad interconnect may vertically align with a center of the second pad interconnect.

In some implementations, an electrical path to and/or from an active region 122 may include at least one die interconnect from the plurality of die interconnects 142, at least one through substrate via from the plurality of through substrate vias 121 (e.g., for back side power delivery). In some implementations, an electrical path to and/or from an active region 122 may include at least one die interconnect from the plurality of die interconnects 142, at least one pad interconnect from the plurality of pad interconnects 101, at least one metallization interconnect from the plurality of metallization interconnects 103, at least one metallization interconnect from the plurality of metallization interconnects 105 and/or at least one solder interconnect from the plurality of solder interconnects 110.

In some implementations, the pad interconnect 101a, the metallization interconnect 103a, the metallization interconnect 105a, the metallization interconnect 105b, the metallization interconnect 105c, the solder interconnect 110a and/or the solder interconnect 110b may be part of electrical path configured for a first power (e.g., for front side power delivery).

In some implementations, the pad interconnect 101b, the pad interconnect 101c, the metallization interconnect 103b, the pad metallization interconnect 105d, the pad metallization interconnect 105e, the solder interconnect 110c and/or the solder interconnect 110d may be part of electrical path configured for a second power. The second power may be different from the first power.

In some implementations, the pad interconnect 101d, the metallization interconnect 103c, the metallization interconnect 105f, and/or the solder interconnect 110e may be part of electrical path configured for a signal (e.g., input/output signal).

FIG. 1 illustrates an example of an integrated device 100 that has a compact form factor while still providing high density interconnects. For example, the integrated device 100 may include a reduced number of metal layers above the die interconnection 104, which is made possible through the configuration of the metallization interconnects 103. This may reduce the overall size of the integrated device 100. Moreover, the integrated device 100 may be more cost effective to fabricate than other comparable integrated devices since the integrated device 100 may be fabricated by a single supplier. For example, the plurality of metallization interconnects 103 and/or the plurality of metallization interconnects 105 may be fabricated as part of the process for fabricating the die interconnection 104, which can help reduce the overall cost of the integrated device 100.

Another advantage is that by reducing the number of metal layers for the plurality of metallization interconnects, smaller and tighter pitch may be provided for metallization interconnects, step pad interconnects and/or under bump metallization interconnects. In some implementations, the pitch for metallization interconnects, step pad interconnects and/or under bump metallization interconnects may be in a range of about 10-50 micrometers.

Additionally, as mentioned above, the step pad interconnects provide additional surface area for solder to couple to, and is thus less likely to spread out. Therefore, the use of the step pad interconnects helps provide tighter pitch between interconnects (e.g., bump interconnects), since solder is less likely to spread away from the step pad interconnects, which allows the step pad interconnects to be closer to each other. Thus, the step pad interconnects may help provide higher density interconnects (e.g., more electrical paths for a given area and/or region), which can help improve the overall performance of the integrated device. In some implementations, the pitch between adjacent and/or neighboring step pad interconnects may be in a range of about 10-50 micrometers. The above advantages are applicable to any of the integrated devices described in the disclosure.

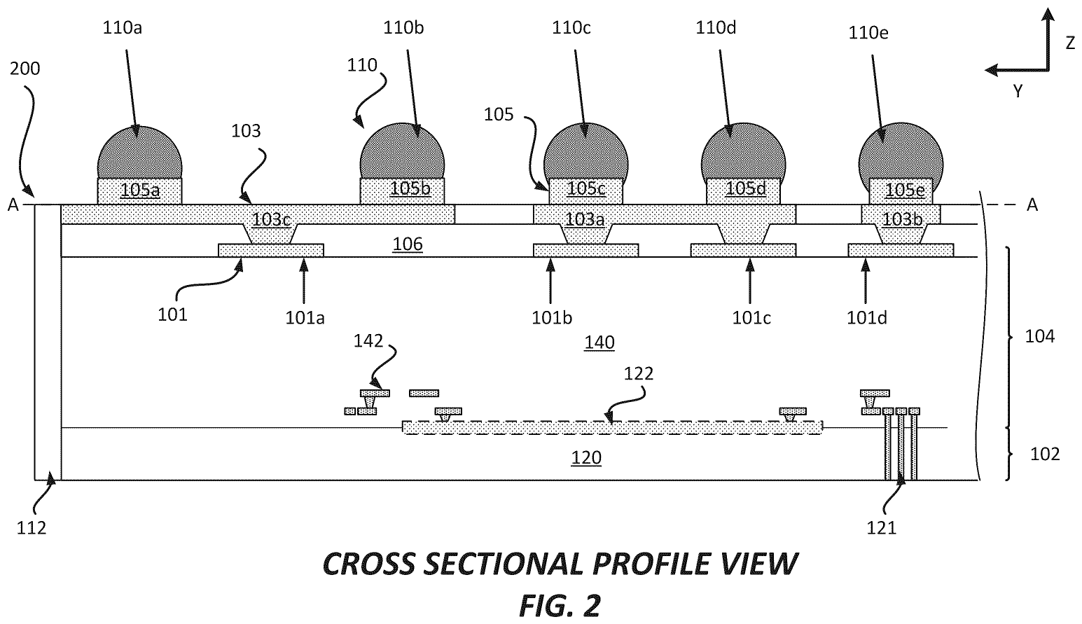

FIG. 2 illustrates an example of an integrated device 200. The integrated device 200 is similar to the integrated device 100, and may include similar components that are arranged and/or configured in a similar manner as the integrated device 100. However, the integrated device 200 may include additional components and/or components that are arranged and/or configured differently. The integrated device 200 includes a die substrate base 102 and a die interconnection 104. The integrated device 200 includes a plurality of metallization interconnects 103, a plurality of metallization interconnects 105, a plurality of solder interconnects 110, and an encapsulation layer 112. The plurality of metallization interconnects 103 of the integrated device 200 may be relatively thicker than the plurality of metallization interconnects 103 of the integrated device 100. The integrated device 200 may provide the same or similar advantages as the advantages described for the integrated device 100. In a similar manner as described for FIG. 1, the integrated device 200 includes a plurality of step pad interconnects which may be defined based on a portion of a metallization interconnect from the plurality of metallization interconnects 103 and a portion of metallization interconnect from the plurality of metallization interconnects 105. For example, the metallization interconnect 105c and a first portion of the metallization interconnect 103a may define a step pad interconnect for the integrated device 200. In another example, the metallization interconnect 105d and a second portion of the metallization interconnect 103a may define another step pad interconnect for the integrated device 200. In another example, the metallization interconnect 105e and the metallization interconnect 103b may define yet another step pad interconnect for the integrated device 200.

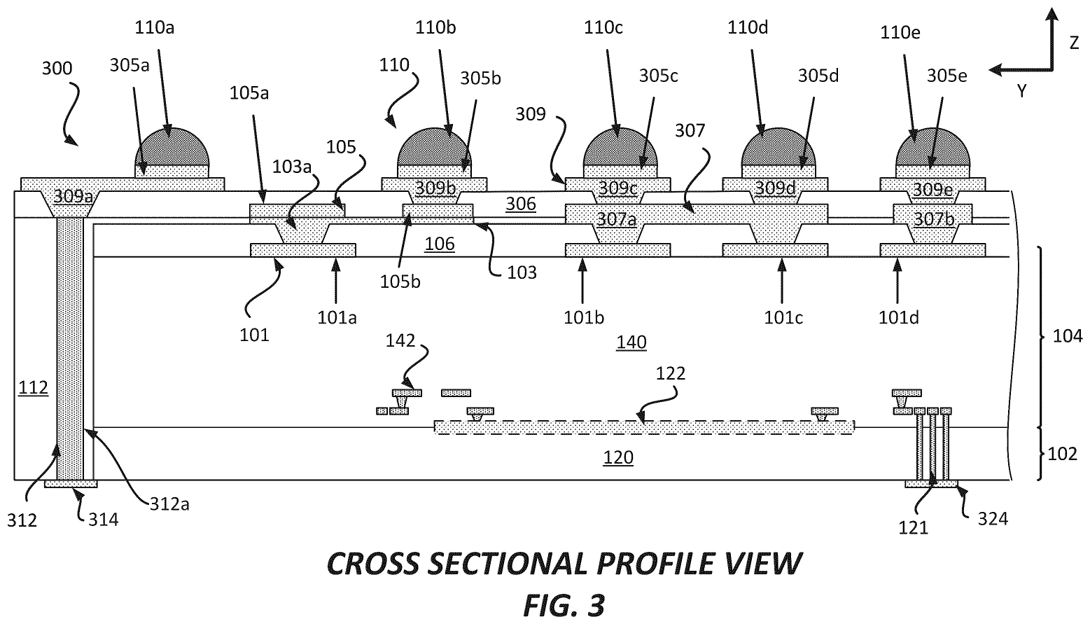

FIG. 3 illustrates an example of an integrated device 300. The integrated device 300 is similar to the integrated device 100, and may include similar components that are arranged and/or configured in a similar manner as the integrated device 100. However, the integrated device 300 may include additional components and/or components that are arranged and/or configured differently. The integrated device 300 includes a die substrate base 102 and a die interconnection 104. The integrated device 300 includes a plurality of metallization interconnects 103, a plurality of metallization interconnects 105, a plurality of metallization interconnects 307 and a plurality of metallization interconnects 309, a plurality of solder interconnects 110, a plurality of interconnects 312, a plurality of metallization interconnects 314, a plurality of metallization interconnects 324, an encapsulation layer 112, a passivation layer 106 and a passivation layer 306.

The plurality of metallization interconnects 103 may be coupled to and touch the plurality of pad interconnects 101. The plurality of metallization interconnects 105 may be coupled to and touch the plurality of metallization interconnects 103. The plurality of metallization interconnects 309 may be coupled to and touch the plurality of metallization interconnects 105. The plurality of metallization interconnects 307 may be coupled to and touch the plurality of pad interconnects 101. The plurality of metallization interconnects 309 may be coupled to and touch the plurality of metallization interconnects 307. The plurality of metallization interconnects 305 may be coupled to and touch the plurality of metallization interconnects 309. The plurality of solder interconnects 110 may be coupled to and touch the plurality of metallization interconnects 305.

The plurality of pad interconnects 101 may include a pad interconnect 101a, a pad interconnect 101b, a pad interconnect 101c and a pad interconnect 101d. The plurality of metallization interconnects 103 may include a metallization interconnect 103a, a metallization interconnect 103b, a metallization interconnect 103c and a metallization interconnect 103d. The plurality of metallization interconnects 105 may include a metallization interconnect 105a and a metallization interconnect 105b. The plurality of metallization interconnects 307 may include a metallization interconnect 307a and a metallization interconnect 307b.

The plurality of metallization interconnects 309 may include a metallization interconnect 309a, a metallization interconnect 309b, a metallization interconnect 309c, a metallization interconnect 309d and a metallization interconnect 309c. The plurality of metallization interconnects 305 may include a metallization interconnect 305a, a metallization interconnect 305b, a metallization interconnect 305c, a metallization interconnect 305d and a metallization interconnect 305c.

Some of the metallization interconnects from the plurality of metallization interconnects 305 and/or the plurality of metallization interconnects 309 may be configured as step pad interconnects.

In some implementations, a combination of the metallization interconnect 305a and a portion of the metallization interconnect 309a may be configured as a step pad interconnect, such as the step pad interconnect 600 and/or the step pad interconnect 604 described and illustrated in FIG. 6. In some implementations, a combination of the metallization interconnect 305b and a portion of the metallization interconnect 309b may be configured as a step pad interconnect, such as the step pad interconnect 600 described and illustrated in FIG. 6. In some implementations, a combination of the metallization interconnect 305c and a portion of the metallization interconnect 309c may be configured as a step pad interconnect, such as the step pad interconnect 600 and/or the step pad interconnect 604 described and illustrated in FIG. 6.

In some implementations, a combination of the metallization interconnect 305d and a portion of the metallization interconnect 309d may be configured as a step pad interconnect, such as the step pad interconnect 600 and/or the step pad interconnect 604 described and illustrated in FIG. 6. In some implementations, a combination of the metallization interconnect 305e and a portion of the metallization interconnect 309e may be configured as a step pad interconnect, such as the step pad interconnect 600 and/or the step pad interconnect 604 described and illustrated in FIG. 6.

FIG. 3 illustrates that the plurality of solder interconnects 110 are coupled to and touch step pad interconnects. The solder interconnect 110a may be coupled to and touch the metallization interconnect 305a. The solder interconnect 110a may be coupled to and touch the metallization interconnect 305a and a portion of the metallization interconnect 309a. The solder interconnect 110b may be coupled to and touch the metallization interconnect 305b. The solder interconnect 110b may be coupled to and touch the metallization interconnect 305b and a portion of the metallization interconnect 309b. The solder interconnect 110c may be coupled to and touch the metallization interconnect 305c. The solder interconnect 110c may be coupled to and touch the metallization interconnect 305c and a portion of the metallization interconnect 309c. The solder interconnect 110d may be coupled to and touch the metallization interconnect 305d. The solder interconnect 110d may be coupled to and touch the metallization interconnect 305d and a portion of the metallization interconnect 309d. The solder interconnect 110e may be coupled to and touch the metallization interconnect 305e. The solder interconnect 110e may be coupled to and touch the metallization interconnect 305e and a portion of the metallization interconnect 309e. The solder interconnect 110c may vertically overlap with the pad interconnect 101b. The metallization interconnect 305c may vertically overlap with the pad interconnect 101b. The solder interconnect 110d may vertically overlap with the pad interconnect 101c. The metallization interconnect 305d may vertically overlap with the pad interconnect 101c. The solder interconnect 110e may vertically overlap with the pad interconnect 101d. The metallization interconnect 305c may vertically overlap with the pad interconnect 101d.

The plurality of interconnects 312 may extend through the encapsulation layer 112. The plurality of interconnects 312 may include an interconnect 312a. The interconnect 312a may be a via interconnect. The metallization interconnect 309a may be coupled to and touch the interconnect 312a. The plurality of metallization interconnects 309 may be coupled to the plurality of interconnects 312. The plurality of metallization interconnects 314 may include a plurality of backside metallization interconnects.

The plurality of metallization interconnects 324 may be coupled to and touch the plurality of through substrate vias 121. The plurality of metallization interconnects 324 may include a plurality of backside metallization interconnects.

It is noted that different implementations may use solder interconnects with different materials, shapes and/or sizes. For example, one or more solder interconnects from the plurality of solder interconnects 110 may have a dome shape. In some implementations, one or more solder interconnects from the plurality of solder interconnects 110 may have one or more flat surfaces (e.g., top flat surface, bottom flat surface). Similarly, different implementations may use pad interconnects with different materials, shapes and/or sizes. For example, one or more pad interconnects may include aluminum (Al), copper (Cu), nickel (Ni), gold (Au) and/or platinum (Pt). Any of the interconnects from the plurality of pad interconnects, the plurality of metallization interconnects and/or the plurality of interconnects may include one or more layers of different materials. In some implementations, the plurality of pad interconnects and the plurality of interconnects may form continuous interconnects and/or contiguous interconnects. The advantages described for the integrated device 100 and the integrated device 200 may also apply to the integrated device 300. It should be noted that an integrated device may include landing pad interconnects that are not configured as step pad interconnects. Thus, in some implementations, some of the solder interconnects may be coupled to pad interconnects that are not step pad interconnects. Thus, an integrated device may include a combination of non-step landing pad interconnects and step landing pad interconnects.

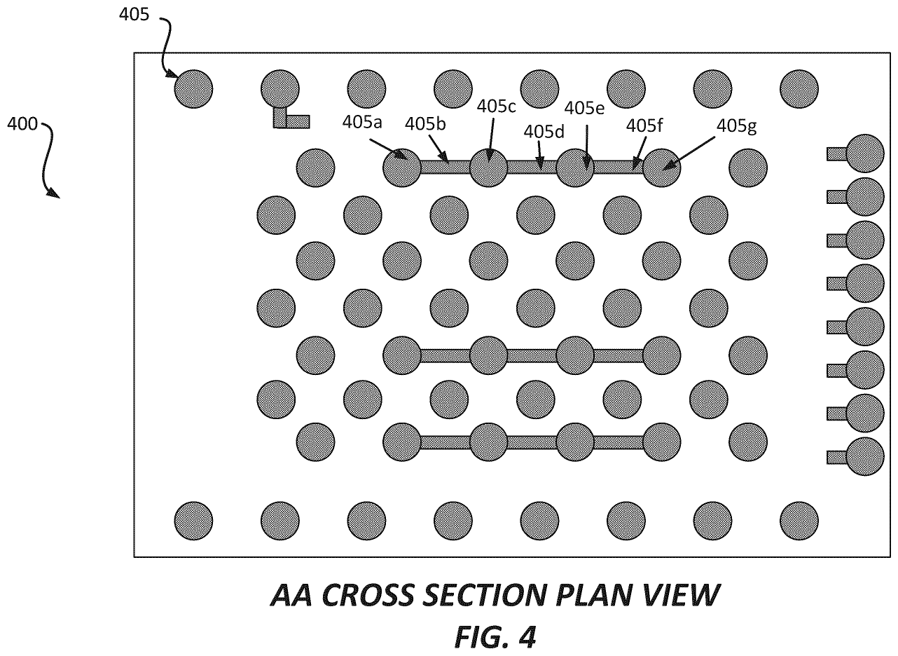

FIG. 4 illustrates an exemplary plan view of a cross section of the integrated device 400. The integrated device 400 may illustrate a representation of an integrated device. The integrated device 400 includes a plurality of metallization interconnects 405. In some implementations, the plurality of metallization interconnects 405 may represent the plurality of metallization interconnects 103, the plurality of metallization interconnects 105, the plurality of metallization interconnects 305 and/or the plurality of metallization interconnects 309. The plurality of metallization interconnects 405 may include a metallization interconnect 405a, a metallization interconnect 405b, a metallization interconnect 405c, a metallization interconnect 405d, a metallization interconnect 405e, a metallization interconnect 405f, and a metallization interconnect 405g. The plurality of metallization interconnects 405 may include non-step landing pad interconnects. The plurality of metallization interconnects 405 may be configured to provide one or more electrical paths for one or more power and/or one or more signals

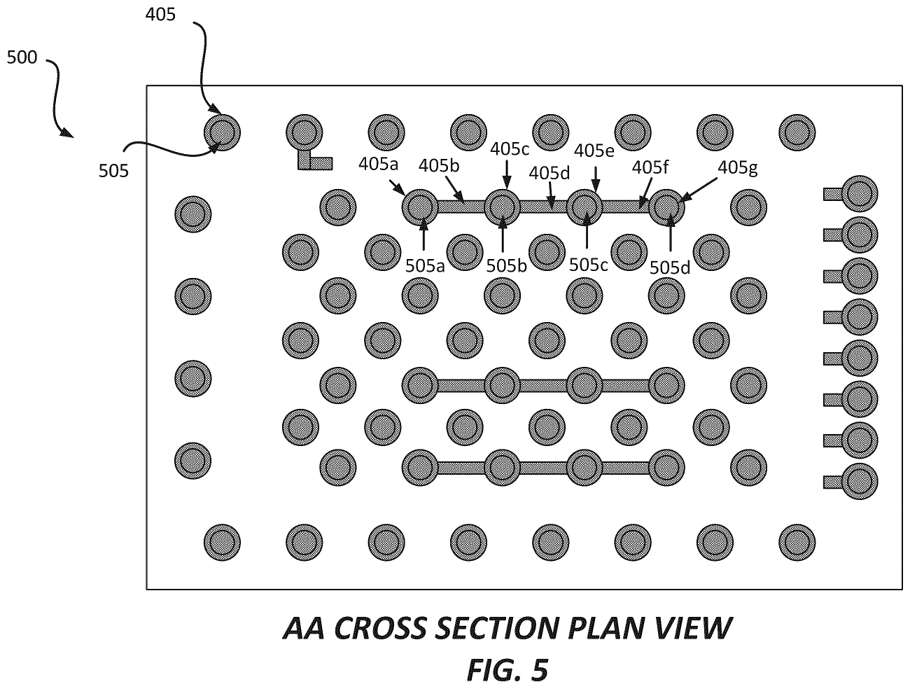

FIG. 5 illustrates an exemplary plan view of a cross section of the integrated device 500. The integrated device 500 may illustrate a representation of the integrated device 100, the integrated device 200, the integrated device 300 and/or any of the integrated devices described in the disclosure. For example, the integrated device 500 may be an illustration of the AA cross section of the integrated device 100.

The integrated device 500 includes a plurality of metallization interconnects 405 and a plurality of metallization interconnects 505. In some implementations, the plurality of metallization interconnects 405 may represent the plurality of metallization interconnects 103 of the integrated device 100. The plurality of metallization interconnects 405 may include a metallization interconnect 405a, a metallization interconnect 405b, a metallization interconnect 405c, a metallization interconnect 405d, a metallization interconnect 405e, a metallization interconnect 405f, and a metallization interconnect 405g.

In some implementations, the plurality of metallization interconnects 505 may represent the plurality of metallization interconnects 105 of the integrated device 100. The plurality of metallization interconnects 505 may include a metallization interconnect 505a, a metallization interconnect 505b, a metallization interconnect 505c, and a metallization interconnect 505d.

The combination of the metallization interconnect 405a and the metallization interconnect 505a may represent a step pad interconnect (e.g., first step pad interconnect). The combination of the metallization interconnect 405c and the metallization interconnect 505b may represent a step pad interconnect (e.g., second step pad interconnect). The combination of the metallization interconnect 405e and the metallization interconnect 505c may represent a step pad interconnect (e.g., third step pad interconnect). The combination of the metallization interconnect 405g and the metallization interconnect 505d may represent a step pad interconnect (e.g., fourth step pad interconnect).

FIG. 5 illustrates that the use of step pad interconnects (e.g., step landing pad interconnects) that are configured to be coupled to solder interconnects, allows the landing pads to be closer to each other for the reasons described above, relative to the non-step landing pad interconnects shown in FIG. 4. Thus, the plurality of metallization interconnects 405 and/or the plurality of metallization interconnects 505 in FIG. 5 may have a smaller pitch and/or size, than the pitch and/or size of the plurality of metallization interconnects 405 of FIG. 4.

FIG. 6 illustrates exemplary views of step pad interconnects. FIG. 6 illustrates a first configuration of a step pad interconnect 600 and a second configuration of a step pad interconnect 604. The step pad interconnect 600 and/or the step pad interconnect 604 may represent and/or replace any of the step pad interconnects described in the disclosure. For example, the step pad interconnect 600 and/or the step pad interconnect 604 may represent any combination of two pad interconnects (e.g., two pad metallization interconnects) that are coupled and touching each other, described in the disclosure. The step pad interconnect 600 and/or the step pad interconnect 604 may each have a shape of a top hat. However, different implementations of a step pad interconnect may have different sizes and/or shapes.

The step pad interconnect 600 includes a first pad interconnect structure 610 and a second pad interconnect structure 612. The step pad interconnect 600 may be a step pad interconnect structure. The second pad interconnect structure 612 may have a smaller circumference, width, diameter and/or radius than the width, diameter and/or radius of the first pad interconnect structure 610. The first pad interconnect structure 610 and the second pad interconnect structure 612 may be continuous and/or contiguous (e.g., for example when the same material is used for the first pad interconnect structure 610 and the second pad interconnect structure 612). The first pad interconnect structure 610 vertically overlaps and/or vertically aligns with the second pad interconnect structure 612. The step pad interconnect 600 is coupled to a trace interconnect 602 (e.g., trace metallization interconnect). For example, the first pad interconnect structure 610 may be coupled to the trace interconnect 602. In some implementations, the first pad interconnect structure 610 may be considered a first pad interconnect and the second pad interconnect structure 612 may be considered a second pad interconnect. Thus, in some implementations, the step pad interconnect 600 may be defined by two pad interconnects with different lateral sizes, that are coupled and stacked together.

The step pad interconnect 604 includes a first pad interconnect structure 640 and a second pad interconnect structure 642. The step pad interconnect 604 may be a step pad interconnect structure. The second pad interconnect structure 642 may have a smaller circumference, width, diameter and/or radius than the circumference, width, diameter and/or radius of the first pad interconnect structure 640. The first pad interconnect structure 640 and the second pad interconnect structure 642 may be continuous and/or contiguous (e.g., for example when the same material is used for the first pad interconnect structure 640 and the second pad interconnect structure 642). The first pad interconnect structure 640 vertically overlaps and/or vertically aligns with the second pad interconnect structure 642. The step pad interconnect 604 is coupled to a via interconnect 605 (e.g., via metallization interconnect). For example, the first pad interconnect structure 640 may be coupled to the via interconnect 605. In some implementations, the first pad interconnect structure 640 may be considered a first pad interconnect and the second pad interconnect structure 642 may be considered a second pad interconnect. Thus, in some implementations, the step pad interconnect 604 may be defined by two pad interconnects with different lateral sizes, that are coupled and stacked together. A first pad interconnect (e.g., first pad metallization interconnect) that vertically aligns with a second pad interconnect (e.g., second pad metallization interconnect) may mean that a center of the first pad interconnect may vertically align with a center of the second pad interconnect.

As shown in FIG. 6, the vertical surface, lateral surfaces and/or the side surface of the second pad interconnect structure 612 and/or the second pad interconnect structure 642 provide additional surface area for solder interconnects to couple to, which helps the solder interconnect from spreading out. This allows step pad interconnects to be closer to each other, without the risk of solder interconnects to flow to a nearby step pad interconnect and causing a short.

It is noted that the configurations of the plurality of metallization interconnects (e.g., 103), the plurality of metallization interconnects (e.g., 105), the plurality of metallization interconnects (e.g., 305), the plurality of metallization interconnects (e.g., 307), and/or the plurality of metallization interconnects (e.g., 309) are not limited to an integrated device. In some implementations, the above metallization interconnects may be implemented as part of a passive device (e.g., die passive device), an interposer (e.g., passive silicon interposer), metallization portion interposer, re-built wafer (e.g., reconstituted wafer) and/or metallization portion on a re-built wafer.

### Exemplary Package Comprising Integrated Device Comprising Step Pad Interconnects

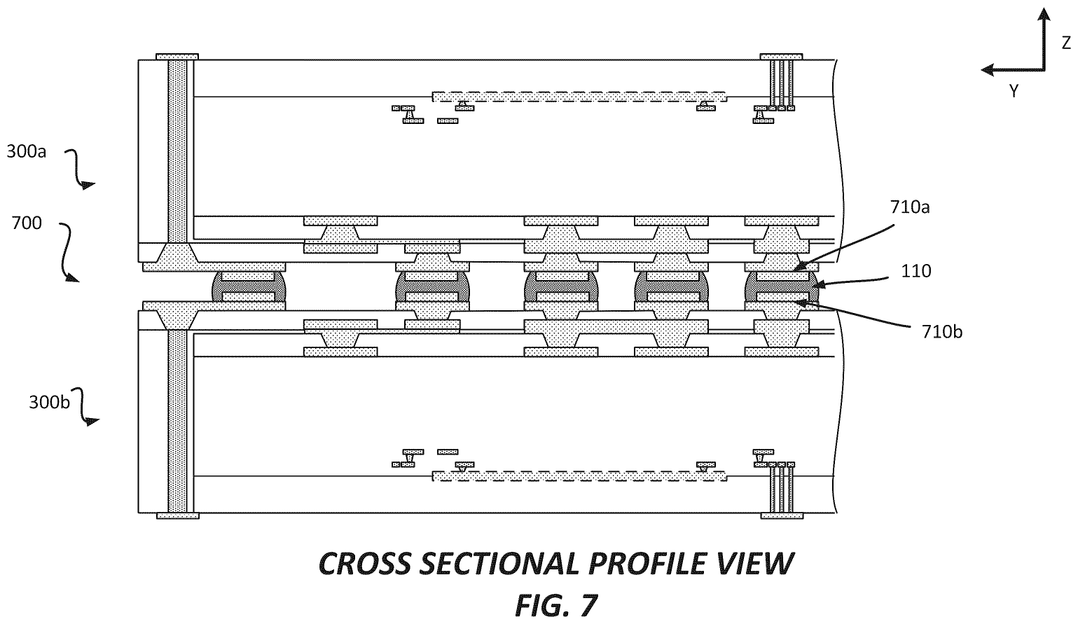

FIG. 7 illustrates a package 700. The package 700 includes an integrated device 300a and an integrated device 300b. The front side of the integrated device 300a is coupled to the front side of the integrated device 300b through a plurality of solder interconnects 110. The plurality of solder interconnects 110 may be coupled to and touch (i) the plurality of metallization interconnects of the integrated device 300a and (ii) the plurality of metallization interconnects of the integrated device 300b. The plurality of solder interconnects 110 may be coupled to and touch (i) the plurality of step pad interconnects 710a of the integrated device 300a and (ii) the plurality of step pad interconnects 710b of the integrated device 300b.

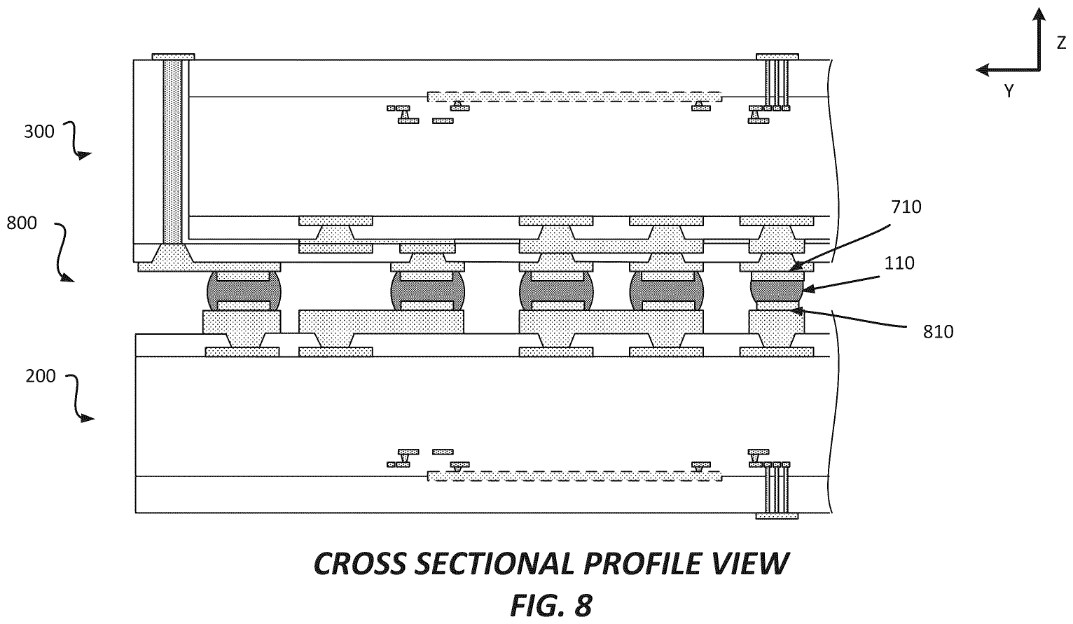

FIG. 8 illustrates a package 800. The package 800 includes an integrated device 300 and an integrated device 200. The front side of the integrated device 300 is coupled to the front side of the integrated device 200 through a plurality of solder interconnects 110. The plurality of solder interconnects 110 may be coupled to and touch (i) the plurality of metallization interconnects of the integrated device 300 and (ii) the plurality of metallization interconnects of the integrated device 200. The plurality of solder interconnects 110 may be coupled to and touch (i) the plurality of step pad interconnects 710 of the integrated device 300 and (ii) the plurality of step pad interconnects 810 of the integrated device 200.

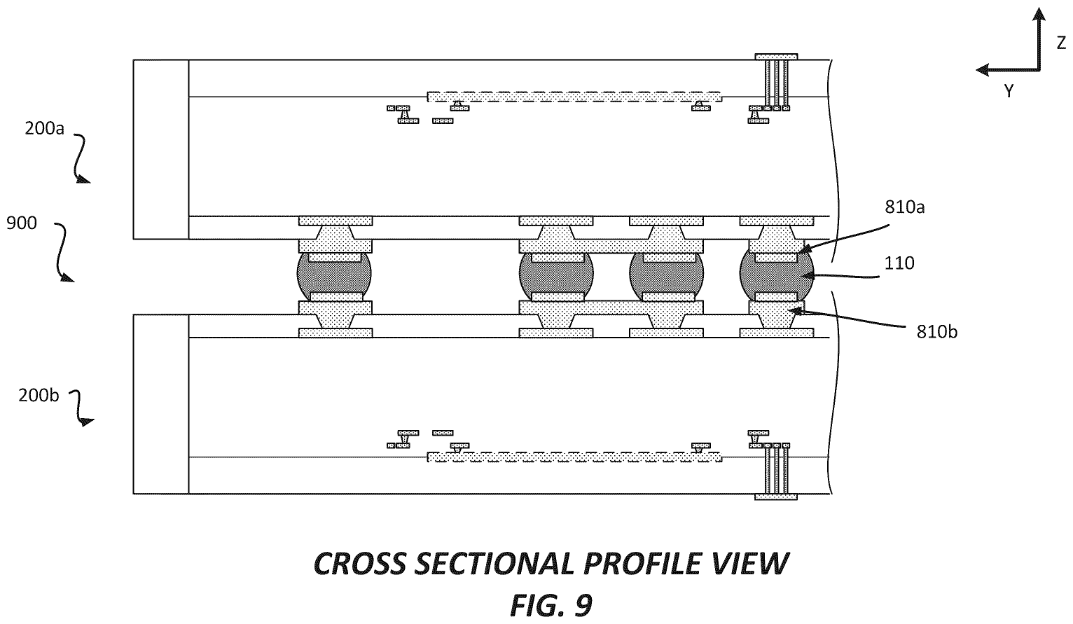

FIG. 9 illustrates a package 900. The package 900 includes an integrated device 200a and an integrated device 200b. The front side of the integrated device 200a is coupled to the front side of the integrated device 200b through a plurality of solder interconnects 110. The plurality of solder interconnects 110 may be coupled to and touch (i) the plurality of metallization interconnects of the integrated device 200a and (ii) the plurality of metallization interconnects of the integrated device 200b. The plurality of solder interconnects 110 may be coupled to and touch (i) the plurality of step pad interconnects 810a of the integrated device 200a and (ii) the plurality of step pad interconnects 810b of the integrated device 200b.

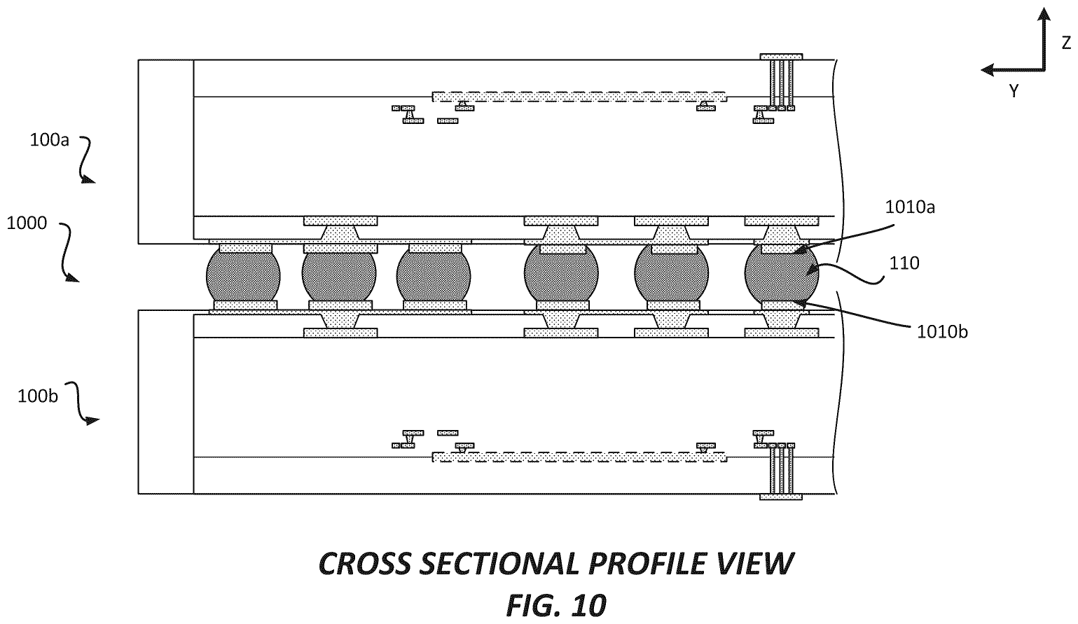

FIG. 10 illustrates a package 1000. The package 1000 includes an integrated device 100a and an integrated device 100b. The front side of the integrated device 100a is coupled to the front side of the integrated device 100b through a plurality of solder interconnects 110. The plurality of solder interconnects 110 may be coupled to and touch (i) the plurality of metallization interconnects of the integrated device 100a and (ii) the plurality of metallization interconnects of the integrated device 100b. The plurality of solder interconnects 110 may be coupled to and touch (i) the plurality of step pad interconnects 1010a of the integrated device 100a and (ii) the plurality of step pad interconnects 1010b of the integrated device 100b.

In some implementations, a front side of an integrated device may be coupled to a back side of an integrated device. The front side of the integrated device may be a side that is farthest away from the die substrate of the integrated device. The back side of the integrated device may be a side that is closest to the die substrate of the integrated device.

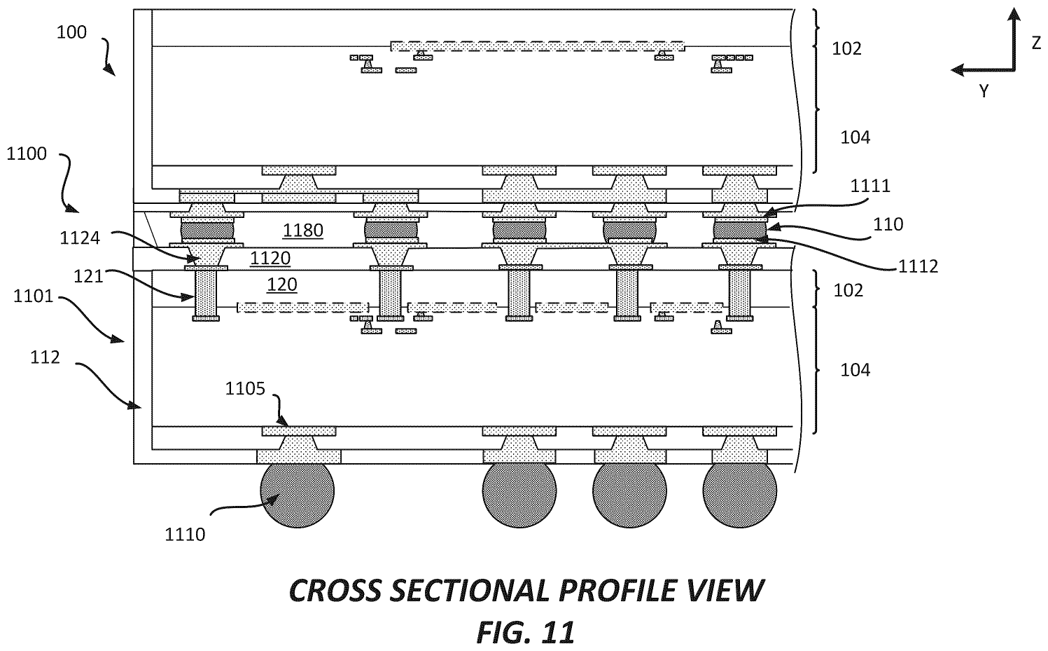

FIG. 11 illustrates a package 1100. The package 1100 includes an integrated device 100 and an integrated device 1101. The front side of the integrated device 100 is coupled to the back side of the integrated device 1101 through a plurality of solder interconnects 110. The plurality of solder interconnects 110 may be coupled to and touch (i) the plurality of metallization interconnects of the integrated device 100 and (ii) the plurality of back side metallization interconnects 1124 of the integrated device 1101. The plurality of back side metallization interconnects 1124 may include step pad interconnects. The plurality of back side metallization interconnects 1124 may be coupled to the plurality of through substrate vias 121. A back side dielectric layer 1120 may be coupled to the die substrate 120. The back side dielectric layer 1120 may be a back side passivation layer. The plurality of solder interconnects 110 may be coupled to and touch (i) the plurality of step pad interconnects 1111 of the integrated device 100 and (ii) the plurality of step pad interconnects 1112 (e.g., back side step pad interconnects) of the integrated device 1101. The integrated device 1101 may be similar to the integrated device 100, the integrated device 200 and/or the integrated device 300, and may include similar components as described for the integrated device 100, the integrated device 200 and/or the integrated device 300. The plurality of solder interconnects 1110 may be coupled to the plurality of metallization interconnects 1105 of the integrated device 1101. There is an underfill 1180 between the integrated device 100 and the integrated device 1101.

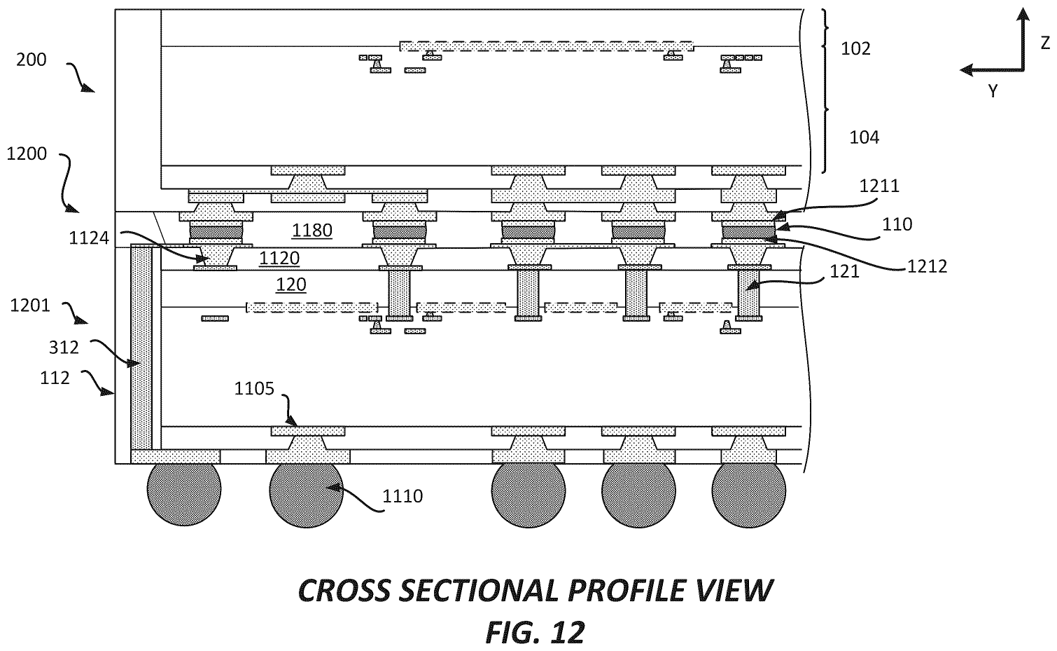

FIG. 12 illustrates a package 1200. The package 1200 includes an integrated device 200 and an integrated device 1201. The front side of the integrated device 200 is coupled to the back side of the integrated device 1201 through a plurality of solder interconnects 110. The plurality of solder interconnects 110 may be coupled to and touch (i) the plurality of metallization interconnects of the integrated device 200 and (ii) the plurality of back side metallization interconnects 1124 of the integrated device 1101. The plurality of back side metallization interconnects 1124 may include step pad interconnects. The plurality of solder interconnects 110 may be coupled to and touch (i) the plurality of step pad interconnects 1211 of the integrated device 200 and (ii) the plurality of step pad interconnects 1212 (e.g., back side step pad interconnects) of the integrated device 1201. A back side dielectric layer 1120 may be coupled to the die substrate 120. The back side dielectric layer 1120 may be a back side passivation layer. The integrated device 1201 may be similar to the integrated device 100, the integrated device 200, the integrated device 300 and/or the integrated device 1101, an may include similar components as described for the integrated device 100, the integrated device 200, the integrated device 300 and/or the integrated device 1101. The plurality of solder interconnects 1110 may be coupled to the plurality of metallization interconnects 1105 of the integrated device 1201. There is an underfill 1180 between the integrated device 200 and the integrated device 1101. FIG. 12 illustrates a plurality of interconnects 312 that extends through the encapsulation layer 112. The plurality of interconnects 312 may be coupled to the plurality of metallization interconnects 1105 and the plurality of back side metallization interconnects 1124.

An integrated device (e.g., 100) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc. . . . ). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advance technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

### Exemplary Sequence for Fabricating an Integrated Device

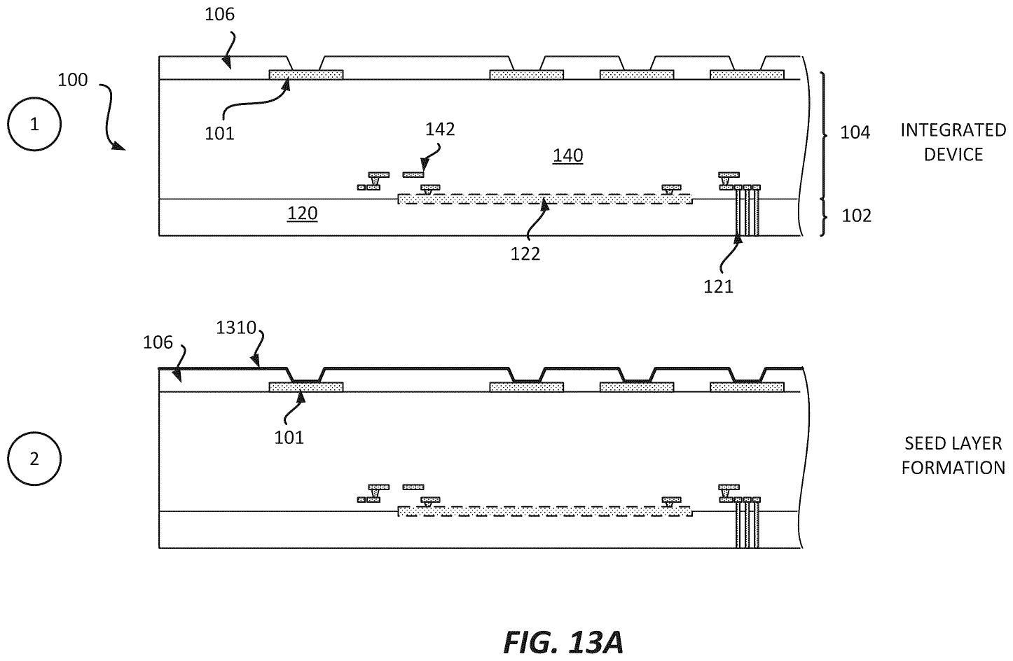

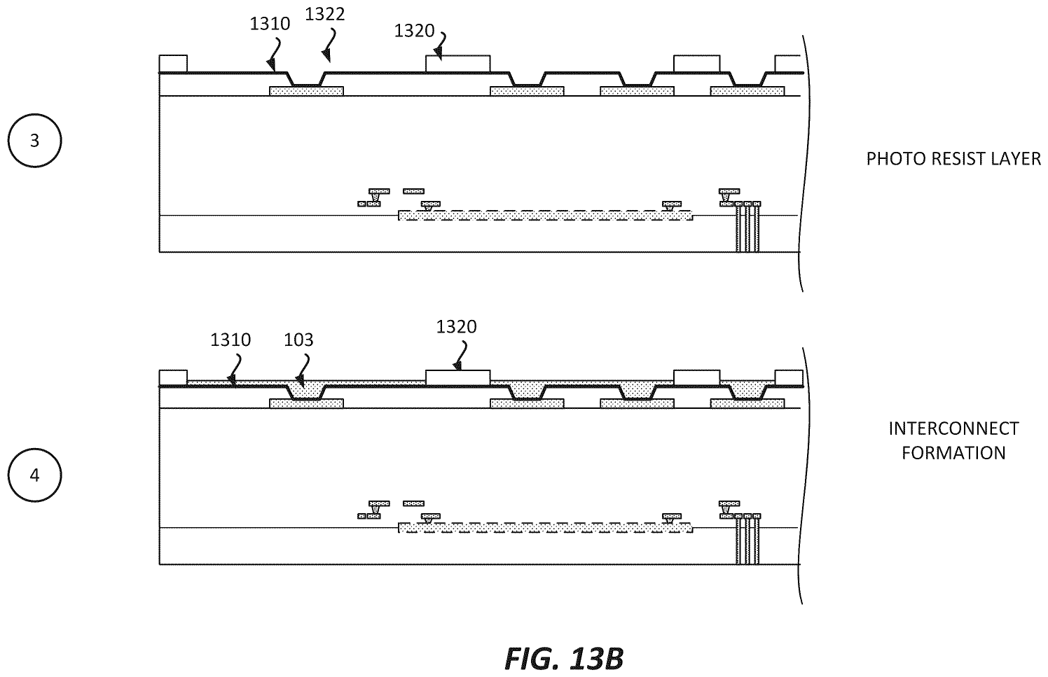

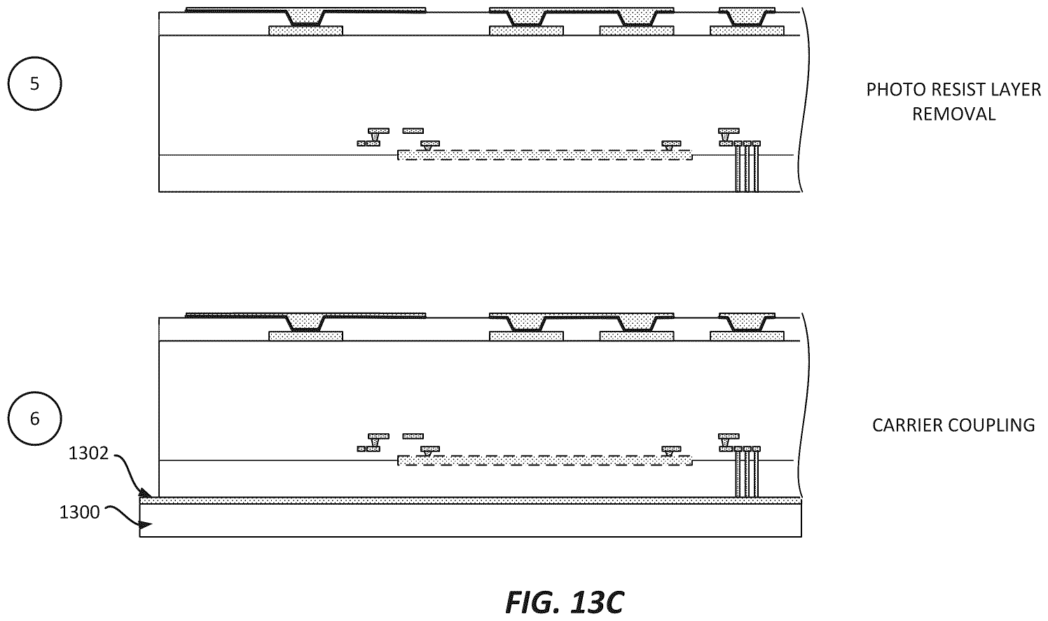

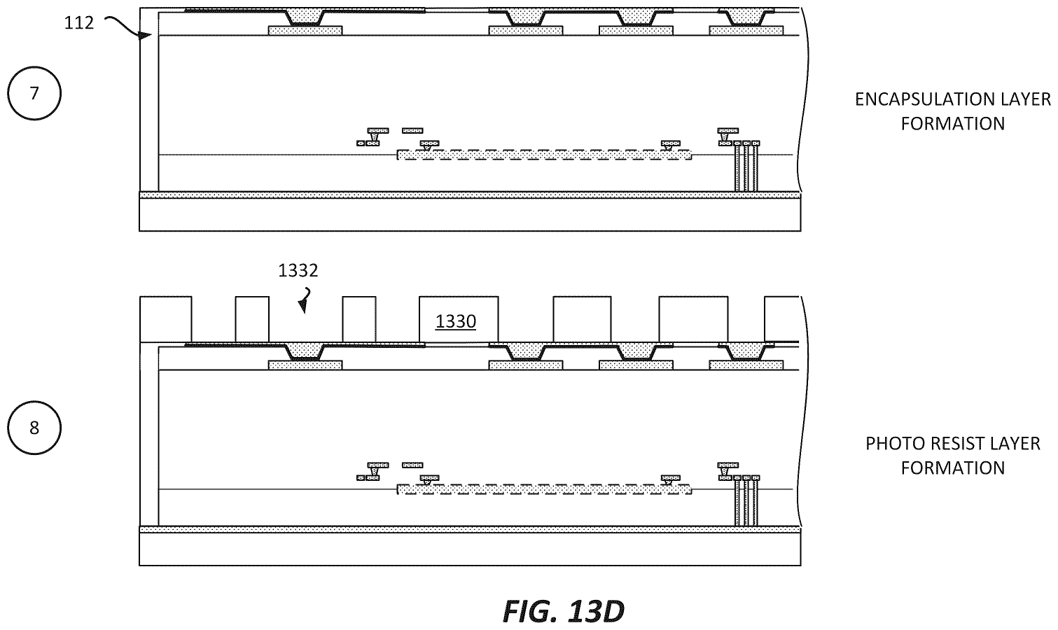

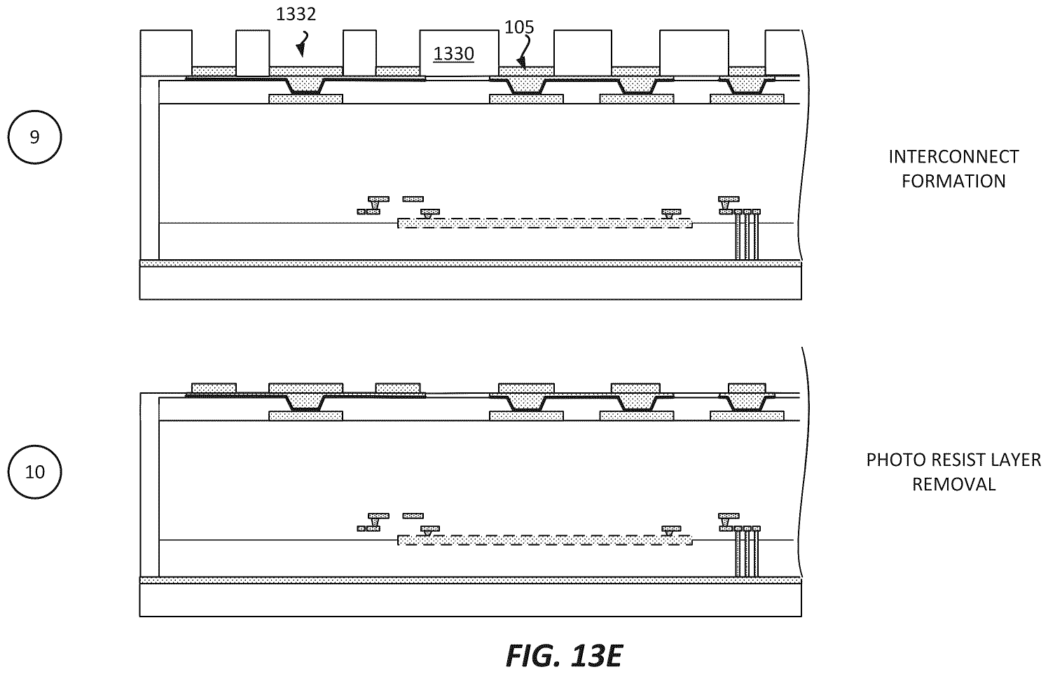

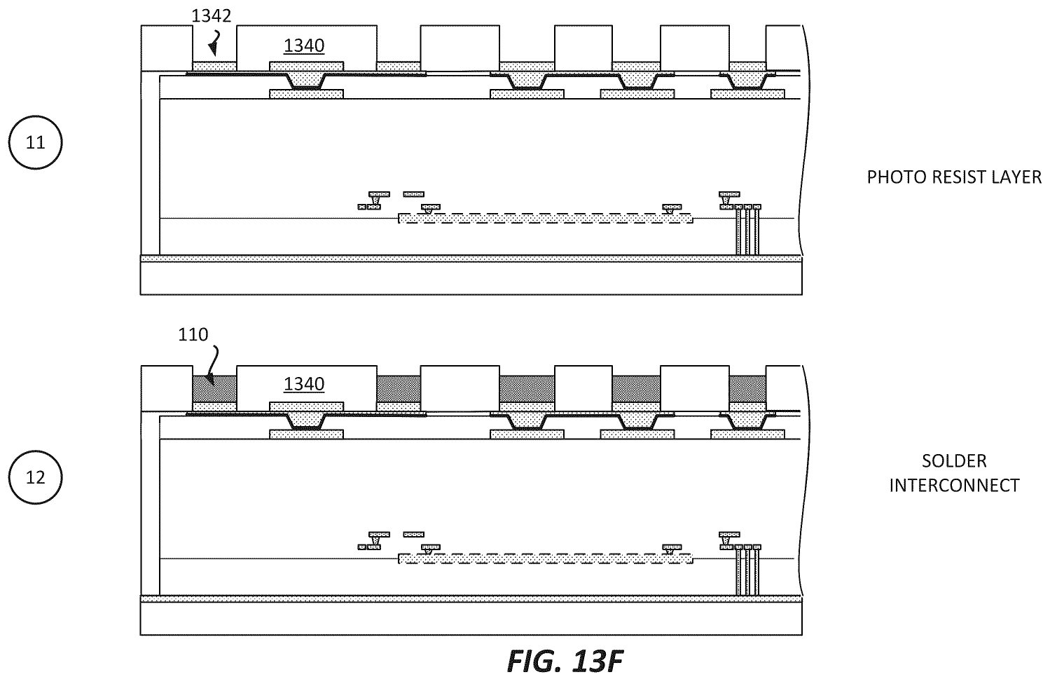

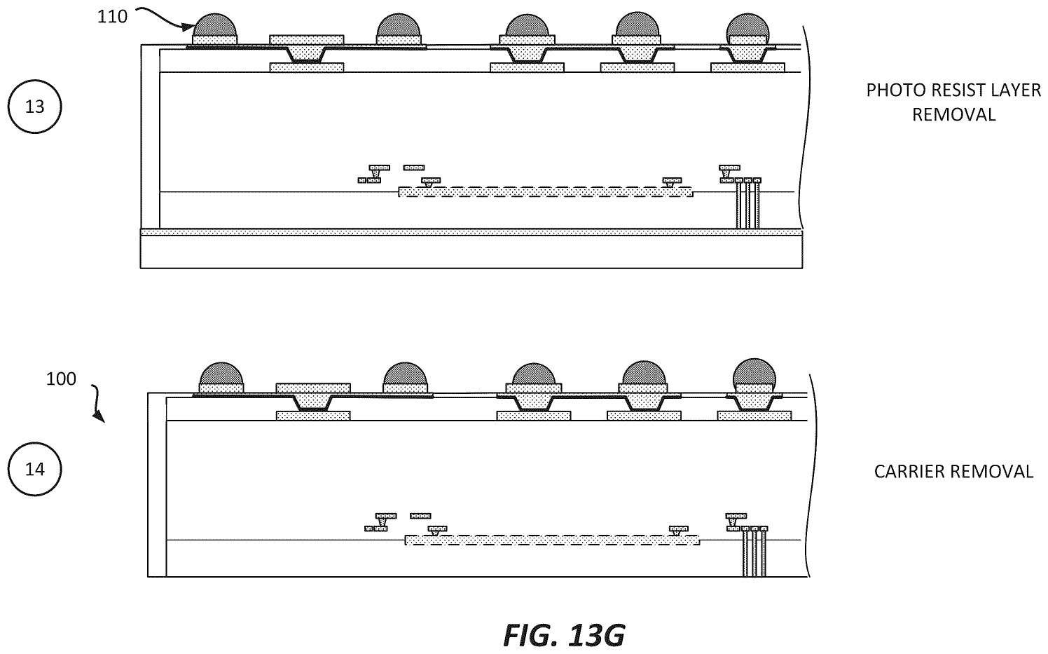

In some implementations, fabricating an integrated device includes several processes. FIGS. 13A-13G illustrate an exemplary sequence for providing or fabricating an integrated device. In some implementations, the sequence of FIGS. 13A-13G may be used to provide or fabricate the integrated device 100. However, the process of FIGS. 13A-13G may be used to fabricate any of the integrated devices described in the disclosure.

It should be noted that the sequence of FIGS. 13A-13G may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 13A, illustrates a state after an integrated device is provided and/or fabricated. The integrated device 100 may include a die substrate base 102. The die substrate base 102 may include a die substrate 120, a die interconnection 104 (e.g., die interconnection portion), a passivation layer 106, and a plurality of pad interconnects 101. The integrated device 100 may include a bare die (e.g., semiconductor bare die). Thus, in some implementations, a bare die that includes a die substrate 120, a die interconnection 104 (e.g., die interconnection portion), at least one passivation layer (e.g., 106) and a plurality of pad interconnects 101, may be provided at stage 1. In some implementations, the integrated device 100 is provided and/or fabricated as part of a wafer. As will be further described below, an integrated device may include additional components and/or other components, which may be fabricated onto the integrated device that is provided at stage 1.

Stage 2 illustrates a state after a seed layer 1310 is formed. The seed layer 1310 may include copper. The seed layer 1310 may be formed over a surface of the passivation layer 106. The seed layer 1310 may also be formed over the plurality of pad interconnects 101. A plating process may be used to form the seed layer 1310.

Stage 3, as shown in FIG. 13B, illustrates a state after a photo resist layer 1320 is formed over the seed layer 1310. The photo resist layer 1320 may include openings 1322. A deposition process, a lamination process, an exposure process and/or a development process may be used to form the photo resist layer 1320.

Stage 4 illustrates a state after a plurality of metallization interconnects 103 are formed. The plurality of metallization interconnects 103 may be formed and coupled to the seed layer 1310. The plurality of metallization interconnects 103 may be formed through the openings 1322 of the photo resist layer 1320. A plating process may be used to form the plurality of metallization interconnects 103. In some implementations, the seed layer 1310 may be considered part of the plurality of metallization interconnects 103. Thus, in some implementations, the plurality of metallization interconnects 103 may include the seed layer 1310. The seed layer 1310 may be considered part of the plurality of metallization interconnects 103.

Stage 5, as shown in FIG. 13C, illustrates a state after the photo resist layer 1320 is removed. A stripping process may be used to remove the photo resist layer 1320.

Stage 6 illustrates a state after the integrated device 100 is placed and coupled to a carrier 1300 through an adhesive 1302.

Stage 7, as shown in FIG. 13D, illustrates a state after an encapsulation layer 112 is formed and coupled to the integrated device 100. The encapsulation layer 112 may be coupled to a side surface and/or a side wall of the integrated device 100. The encapsulation layer 112 may touch a side surface of the passivation layer 106, a side surface of the dielectric layer 140 and/or a side surface of the die substrate 120. The encapsulation layer 112 may be formed over the passivation layer 106. The encapsulation layer 112 may include a mold, a resin and/or an epoxy. A compression molding process, a transfer molding process, or a liquid molding process may be used to form the encapsulation layer 112.

Stage 8 illustrates a state after a photo resist layer 1330 is formed over the plurality of metallization interconnects 103. The photo resist layer 1330 may include openings 1332. A deposition process, a lamination process, an exposure process and/or a development process may be used to form the photo resist layer 1330.

Stage 9, as shown in FIG. 13E, illustrates a state after a plurality of metallization interconnects 105 are formed. The plurality of metallization interconnects 105 may be formed and coupled to the plurality of metallization interconnects 103. The plurality of metallization interconnects 105 may be formed through the openings 1332 of the photo resist layer 1330. A plating process may be used to form the plurality of metallization interconnects 105.

Stage 10 illustrates a state after the photo resist layer 1330 is removed. A stripping process may be used to remove the photo resist layer 1330.

Stage 11, as shown in FIG. 13F, illustrates a state after a photo resist layer 1340 is formed. The photo resist layer 1340 may include openings 1342. A deposition process, a lamination process, an exposure process and/or a development process may be used to form the photo resist layer 1340.

Stage 12 illustrates a state after a plurality of solder interconnects 110 are formed and coupled to the plurality of metallization interconnects 105. A pasting process may be used to form the plurality of solder interconnects 110 through the openings 1342 of the photo resist layer 1340. A solder reflow process may be used to couple the plurality of solder interconnects 110 to the plurality of metallization interconnects 105.

Stage 13, as shown in FIG. 13G, illustrates a state after the photo resist layer 1340 is removed. A stripping process may be used to remove the photo resist layer 1340.

Stage 14 illustrates after the integrated device 100 is decoupled from the carrier 1300. The adhesive 1302 and the carrier 1300 may be detached from the integrated device 100.

### Exemplary Flow Diagram of a Method for Fabricating an Integrated Device

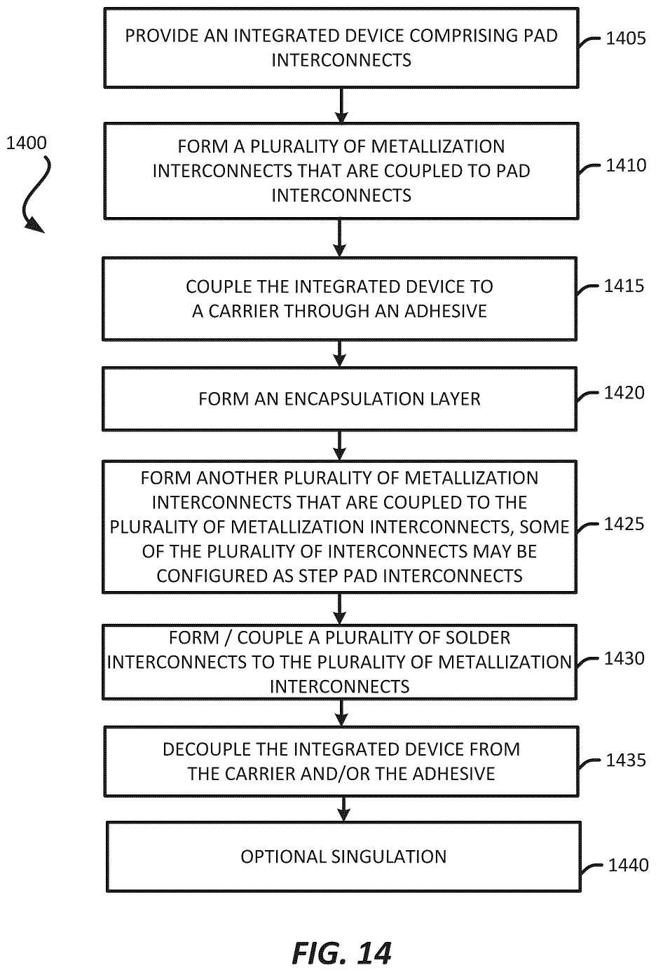

In some implementations, fabricating an integrated device includes several processes. FIG. 14 illustrates an exemplary flow diagram of a method 1400 for providing or fabricating an integrated device. In some implementations, the method 1400 of FIG. 14 may be used to provide or fabricate the integrated device 100 of FIG. 1 described in the disclosure. However, the method 1400 may be used to provide or fabricate any of the integrated devices described in the disclosure.

It should be noted that the method 1400 of FIG. 14 may combine one or more processes in order to simplify and/or clarify the method for providing or fabricating an integrated device. In some implementations, the order of the processes may be changed or modified.

The method provides (at 1405) an integrated device that includes a die substrate, a die interconnection and a plurality of pad interconnects, and couples the integrated device to a carrier through an adhesive. Stage 1, as shown in FIG. 13A, illustrates a state after an integrated device is provided and/or fabricated. The integrated device 100 may include a die substrate base 102. The die substrate base 102 may include a die substrate 120, a die interconnection 104 (e.g., die interconnection portion), a passivation layer 106, and a plurality of pad interconnects 101. The integrated device 100 may include a bare die (e.g., semiconductor bare die). Thus, in some implementations, a bare die that includes a die substrate 120, a die interconnection 104 (e.g., die interconnection portion), at least one passivation layer (e.g., 106) and a plurality of pad interconnects 101, may be provided at stage 1. In some implementations, the integrated device 100 is provided and/or fabricated as part of a wafer. As will be further described below, an integrated device may include additional components and/or other components, which may be fabricated onto the integrated device that is provided at stage 1.

The method forms (at 1410) a plurality of metallization interconnects coupled to the plurality of pad interconnects. Stage 2 of FIG. 13A through stage 5 of FIG. 13C illustrates an example of forming a plurality of metallization interconnects. Stage 2 of FIG. 13A, illustrates a state after a seed layer 1310 is formed. The seed layer 1310 may include copper. The seed layer 1310 may be formed over a surface of the passivation layer 106. The seed layer 1310 may also be formed over the plurality of pad interconnects 101. A plating process may be used to form the seed layer 1310. Stage 3 of FIG. 13B, illustrates a state after a photo resist layer 1320 is formed over the seed layer 1310. The photo resist layer 1320 may include openings 1322. A deposition process, a lamination process, an exposure process and/or a development process may be used to form the photo resist layer 1320. Stage 4 of FIG. 13B, illustrates a state after a plurality of metallization interconnects 103 are formed. The plurality of metallization interconnects 103 may be formed and coupled to the seed layer 1310. The plurality of metallization interconnects 103 may be formed through the openings 1322 of the photo resist layer 1320. A plating process may be used to form the plurality of metallization interconnects 103. In some implementations, the seed layer 1310 may be considered part of the plurality of metallization interconnects 103. Thus, in some implementations, the plurality of metallization interconnects 103 may include the seed layer 1310. Stage 5 of FIG. 13C, illustrates a state after the photo resist layer 1320 is removed. A stripping process may be used to remove the photo resist layer 1320.

The method couples (at 1415) the integrated device to a carrier. Stage 6 of FIG. 13C, illustrates a state after the integrated device 100 is placed and coupled to a carrier 1300 through an adhesive 1302.

The method forms and couples (at 1420) an encapsulation layer to the integrated device. Stage 7 of FIG. 13D, illustrates a state after an encapsulation layer 112 is formed and coupled to the integrated device 100. The encapsulation layer 112 may be coupled to a side surface and/or a side wall of the integrated device 100. The encapsulation layer 112 may touch a side surface of the passivation layer 106, a side surface of the dielectric layer 140 and/or a side surface of the die substrate 120. The encapsulation layer 112 may be formed over the passivation layer 106. The encapsulation layer 112 may include a mold, a resin and/or an epoxy. A compression molding process, a transfer molding process, or a liquid molding process may be used to form the encapsulation layer 112.

The method forms (at 1425) a plurality of metallization interconnects. Forming the plurality of metallization interconnects may include forming step pad interconnects. Stage 8 of FIG. 13D, illustrates a state after a photo resist layer 1330 is formed over the plurality of metallization interconnects 103. The photo resist layer 1330 may include openings 1332. A deposition process, a lamination process, an exposure process and/or a development process may be used to form the photo resist layer 1330. Stage 9 of FIG. 13E, illustrates a state after a plurality of metallization interconnects 105 are formed. The plurality of metallization interconnects 105 may be formed and coupled to the plurality of metallization interconnects 103. The plurality of metallization interconnects 105 may be formed through the openings 1332 of the photo resist layer 1330. A plating process may be used to form the plurality of metallization interconnects 105. Stage 10 of FIG. 13E, illustrates a state after the photo resist layer 1330 is removed. A stripping process may be used to remove the photo resist layer 1330.

The method forms and couples (at 1430) a plurality of solder interconnects to step pad interconnects. Stage 11 of FIG. 13F, illustrates a state after a photo resist layer 1340 is formed. The photo resist layer 1340 may include openings 1342. A deposition process, a lamination process, an exposure process and/or a development process may be used to form the photo resist layer 1340. Stage 12 of FIG. 13F, illustrates a state after a plurality of solder interconnects 110 are formed and coupled to the plurality of metallization interconnects 105. A pasting process may be used to form the plurality of solder interconnects 110 through the openings 1342 of the photo resist layer 1340. A solder reflow process may be used to couple the plurality of solder interconnects 110 to the plurality of metallization interconnects 105. Stage 13 of FIG. 13G, illustrates a state after the photo resist layer 1340 is removed. A stripping process may be used to remove the photo resist layer 1340.

The method decouples (at 1435) the integrated device from the carrier. Stage 14 of FIG. 13G illustrates a state after the integrated device 100 is decoupled from the carrier 1300. The adhesive 1302 and the carrier 1300 may be detached from the integrated device 100.

In some implementations, the integrated device may be one or many integrated device on a wafer. In such instances, the method may singulate (at 1440) wafer to form individual integrated devices.

### Exemplary Package and Integrated Devices

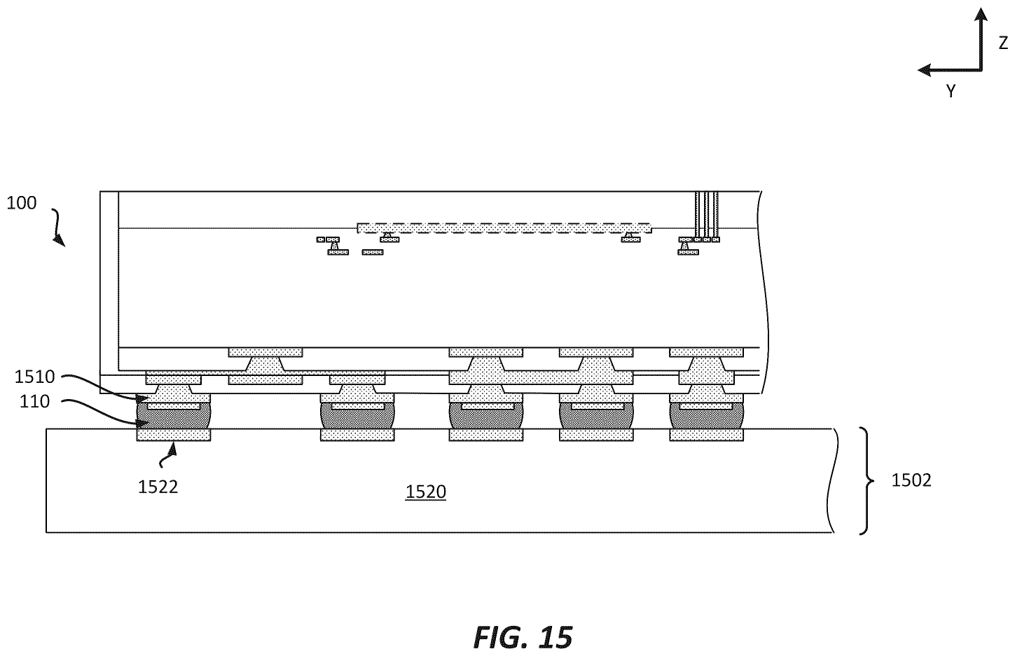

FIG. 15 illustrates a cross sectional profile view of an integrated device 100 that is coupled to a board 1502. The integrated device 100 may be coupled to the board 1502 through the plurality of solder interconnects 110. The board 1502 may include a printed circuit board (PCB). The board 1502 may include a board dielectric layer 1520 and a plurality of board interconnects 1522. Any of the integrated devices described in the disclosure may be coupled to the board. For example the integrated device 200 and/or the integrated device 300 may be coupled to the board 1502 through a plurality of solder interconnects 110. At least some solder interconnect from the plurality of solder interconnects 110 may be coupled to some of the step pad interconnects 1510 of the integrated device 100. In some implementations, the step pad interconnects 1510 may include metallization interconnects from the plurality of metallization interconnects 103 and metallization interconnects from the plurality of metallization interconnects 105.

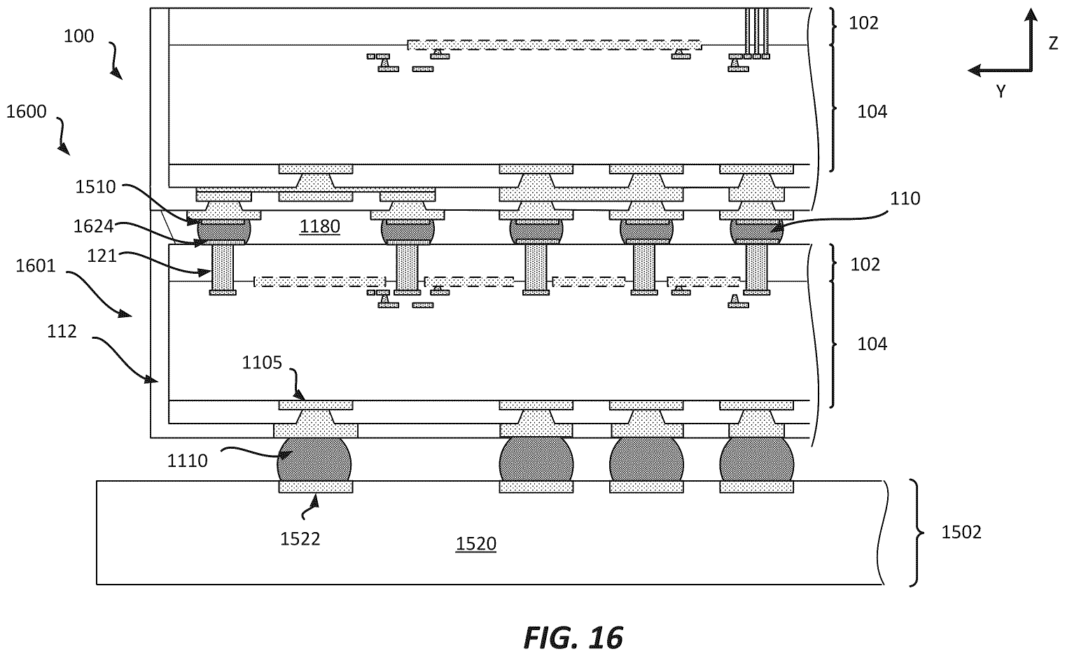

FIG. 16 illustrates a cross section profile view of a package 1600 that includes two integrated devices. The package 1600 includes the integrated device 100 and an integrated device 1601. The package 1600 may be coupled to the board 1502 through the plurality of solder interconnects 1110. At least some solder interconnect from the plurality of solder interconnects 110 may be coupled to some of the step pad interconnects 1510 of the integrated device 100. The integrated device 1601 is similar to the integrated device 1101 and may include similar components as the integrated device 1101. The integrated device 1601 includes a plurality of back side metallization interconnects 1624 that is coupled to the plurality of through substrate vias 121.

It is noted that a package may include any combination of the integrated devices (e.g., 100, 200, 300) described in the disclosure. In some implementations, a package may include integrated devices where a front side of a first integrated device is coupled to a front side of a second integrated device. In some implementations, a package may include integrated devices where a front side of a first integrated device is coupled to a back side of a second integrated device. In some implementations, a package may include integrated devices where a back side of a first integrated device is coupled to a back side of a second integrated device.

### Exemplary Sequence for Fabricating a Package Comprising Integrated Devices

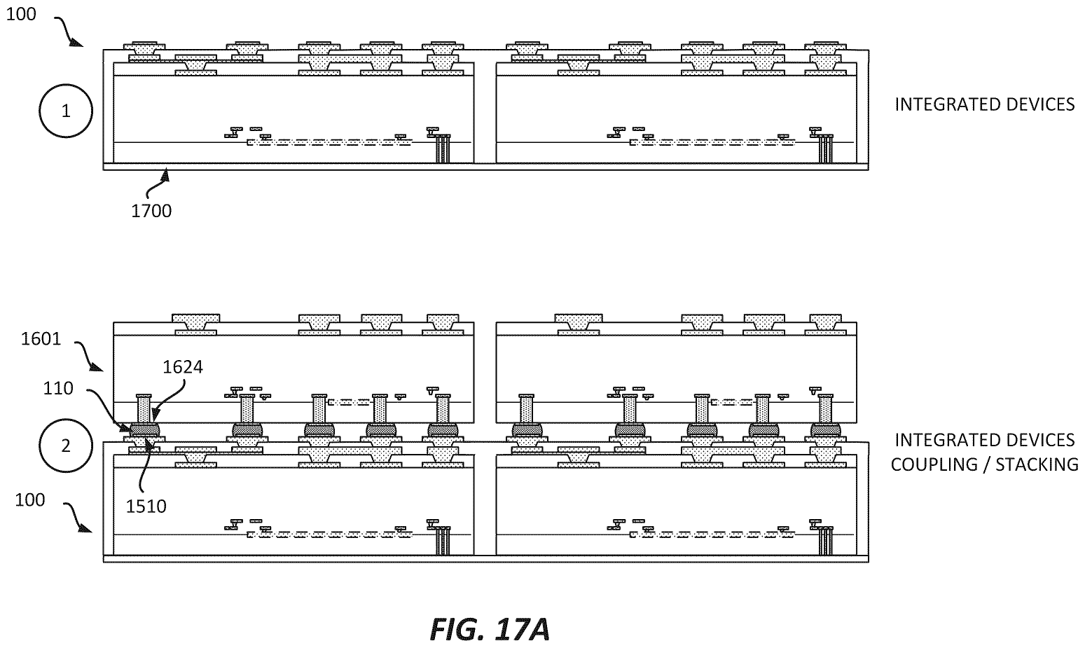

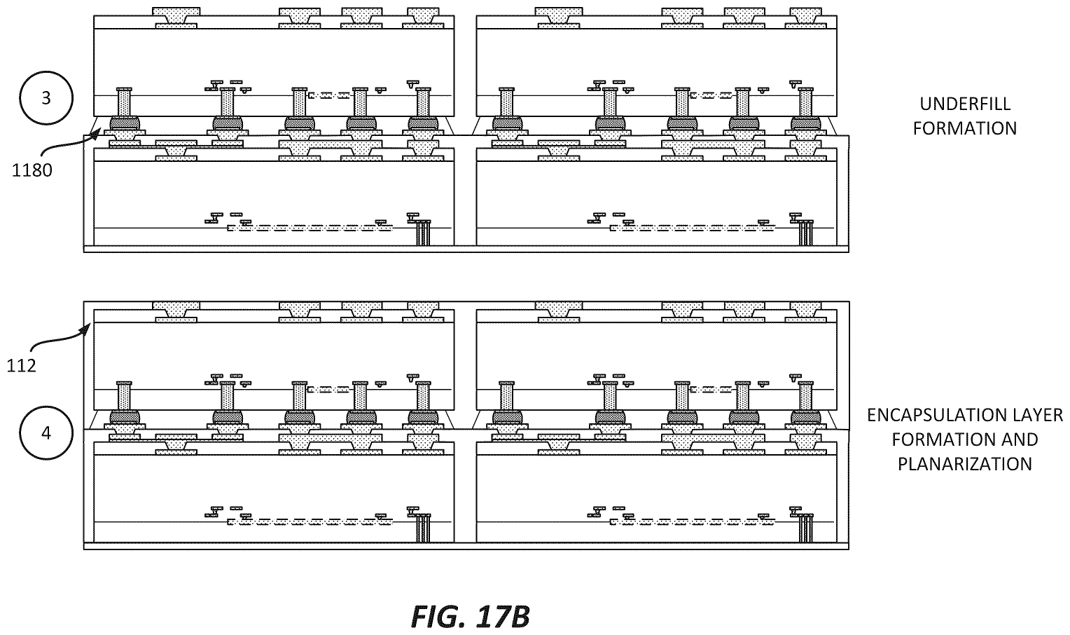

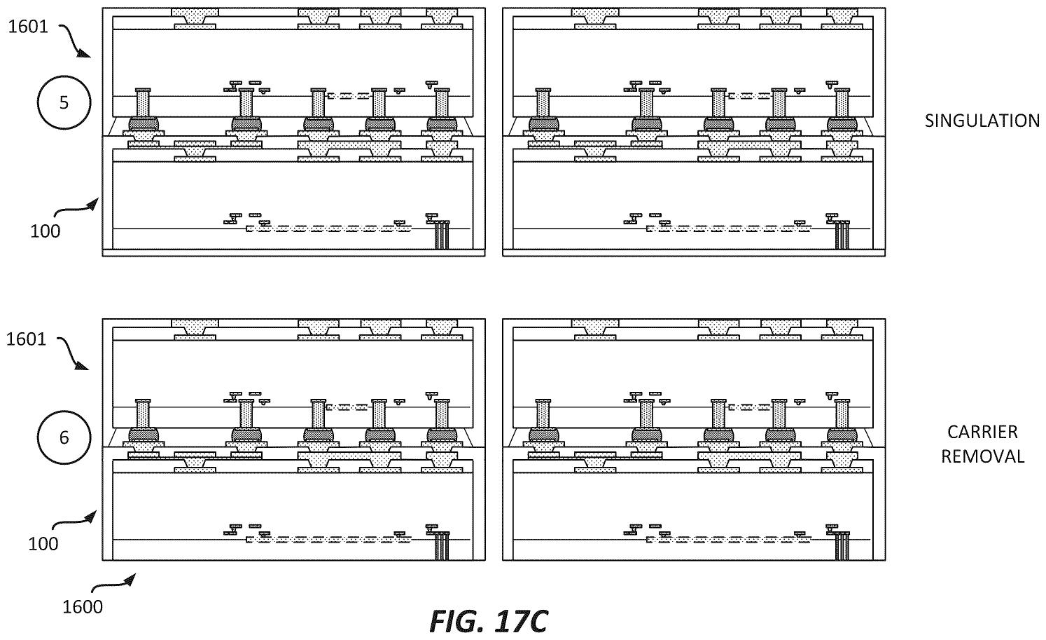

In some implementations, fabricating a package includes several processes. FIGS. 17A-17C illustrate an exemplary sequence for providing or fabricating a package that includes integrated devices. In some implementations, the sequence of FIGS. 17A-17C may be used to provide or fabricate the package 1600 of FIG. 16. However, the process of FIGS. 17A-17C may be used to fabricate any of the packages described in the disclosure.

It should be noted that the sequence of FIGS. 17A-17C may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 17A illustrates a state after several integrated devices (e.g., first integrated devices, 100) are provided and coupled to a carrier 1700. An adhesive may be used to couple the integrated device to the carrier. The several integrated devices may be uncut integrated devices that are part of a wafer.

Stage 2 illustrates a state after several integrated devices (e.g., second integrated devices, 1601) are coupled to the first integrated devices (e.g., 100) through a plurality of solder interconnects (e.g., 110). A solder reflow process may be used to couple the integrated device 1601 (e.g., second integrated device) to the integrated device 100 (e.g. first integrated device). The plurality of solder interconnects 110 may be coupled to (i) the plurality of step pad interconnects 1510 of the integrated device 100 and (ii) the plurality of back side metallization interconnects 1624 of the integrated device 1601.

Stage 3, as shown in FIG. 17B illustrates a state after an underfill 1180 is provided between the integrated device 100 and the integrated device 1601.

Stage 4 illustrates a state after an encapsulation layer 112 is formed and coupled to the integrated device 1601. The encapsulation layer 112 may include a mold, a resin and/or an epoxy. A compression molding process, a transfer molding process, or a liquid molding process may be used to form the encapsulation layer 112.

Stage 5, as shown in FIG. 17C illustrates after singulation of the several integrated devices. A slicing and/or dicing operation may be used to singulate the plurality of integrated devices into a package that includes a first integrated device (e.g., 100) and a second integrated device (e.g., 1601).

Stage 6 illustrates a state after the carrier 1700 is decoupled from the package. The carrier 1700 may be detached or grinded off from the package 1600 that includes integrated device 100 and the integrated device 1601.

### Exemplary Flow Diagram of a Method for Fabricating a Package Comprising Integrated Devices

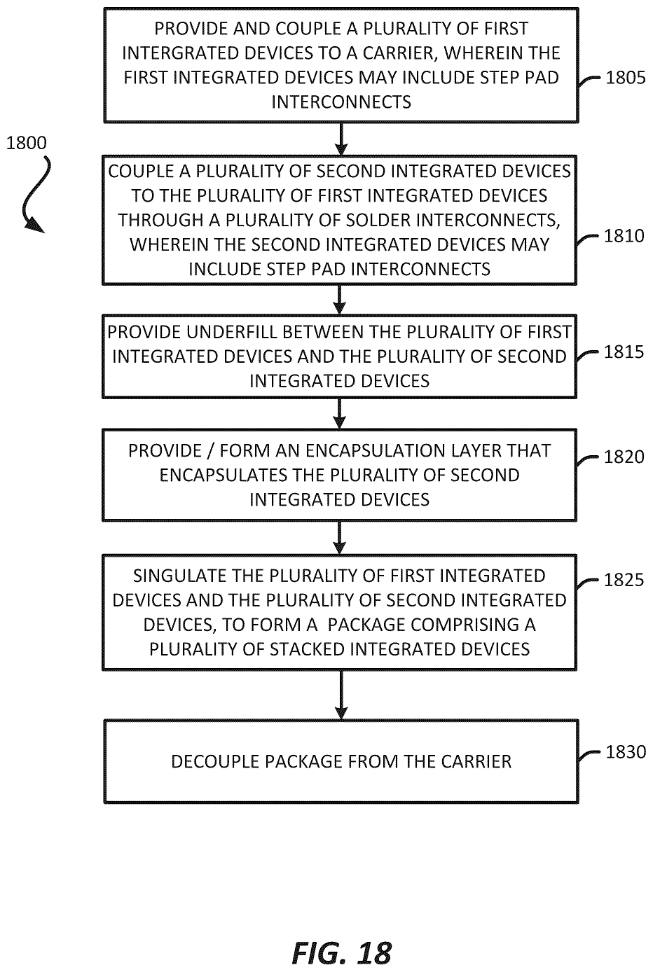

In some implementations, fabricating a package includes several processes. FIG. 18 illustrates an exemplary flow diagram of a method 1800 for providing or fabricating a package comprising integrated devices. In some implementations, the method 1800 of FIG. 18 may be used to provide or fabricate the package 1600 of FIG. 16 described in the disclosure. However, the method 1800 may be used to provide or fabricate any of the packages described in the disclosure.

It should be noted that the method of FIG. 18 may combine one or more processes in order to simplify and/or clarify the method for providing or fabricating a package. In some implementations, the order of the processes may be changed or modified.

The method provides and couples (at 1805) a plurality of first integrated devices to the carrier. Stage 1 of FIG. 17A, illustrates and describes an example of a state after several integrated devices (e.g., first integrated devices, 100) are provided and coupled to a carrier 1700. An adhesive may be used to couple the integrated device to the carrier.

The method couples (at 1810) a plurality of second integrated devices to the plurality of first integrated devices through a plurality of solder interconnects. Stage 2 of FIG. 17A, illustrates and describes an example of a state after several integrated devices (e.g., second integrated devices, 1601) are coupled to the first integrated devices (e.g., 100) through a plurality of solder interconnects (e.g., 110). A solder reflow process may be used to couple the integrated device 1601 (e.g., second integrated device) to the integrated device 100 (e.g. first integrated device).

The method provides (at 1815) an underfill between the plurality of first integrated devices and the plurality of second integrated devices. Stage 3 of FIG. 17B, illustrates and describes an example of a state after an underfill 1180 is provided between the integrated device 100 and the integrated device 1601.

The method forms (at 1820) an encapsulation layer that encapsulates the plurality of second integrated devices. The encapsulation layer may touch a side surface of the plurality of second integrated devices. Stage 4 of FIG. 17B, illustrates and describes an example of a state after an encapsulation layer 112 is formed and coupled to the integrated device 1601. The encapsulation layer 112 may include a mold, a resin and/or an epoxy. A compression molding process, a transfer molding process, or a liquid molding process may be used to form the encapsulation layer 112.

The method singulates (at 1825) the plurality of first integrated devices and the plurality of second integrated devices to form a package that includes a plurality of stacked integrated devices. Stage 5 of FIG. 17C, illustrates and describes an example of a state after singulation of the several integrated devices. A slicing and/or dicing operation may be used to singulate the plurality of integrated devices into a package that includes a first integrated device (e.g., 100) and a second integrated device (e.g., 1601).

The method decouples (at 1830) the carrier from the package. Stage 6 of FIG. 17C, illustrates and describes an example of a state after the carrier 1700 is decoupled from the package. The carrier 1700 may be detached or grinded off from the package 1600 that includes integrated device 100 and the integrated device 1601.

### Exemplary Electronic Devices

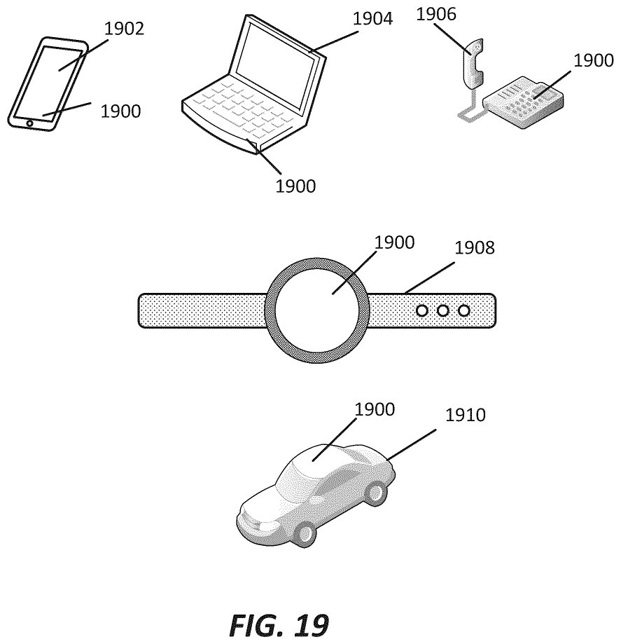

FIG. 19 illustrates various electronic devices that may be integrated with any of the aforementioned device, integrated device, integrated circuit (IC) package, integrated circuit (IC) device, semiconductor device, integrated circuit, die, interposer, package, package on package (POP), System in Package (SiP), or System on Chip (SoC). For example, a mobile phone device 1902, a laptop computer device 1904, a fixed location terminal device 1906, a wearable device 1908, or automotive vehicle 1910 may include a device 1900 as described herein. The device 1900 may be, for example, any of the devices and/or integrated circuit (IC) packages described herein. The devices 1902, 1904, 1906 and 1908 and the vehicle 1910 illustrated in FIG. 19 are merely exemplary. Other electronic devices may also feature the device 1900 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-12, 13A-13G, 14-16, 17A-17C and/or 18-19 may be rearranged and/or combined into a single component, process, feature or function or embodied in several components, processes, or functions. Additional elements, components, processes, and/or functions may also be added without departing from the disclosure. It should also be noted FIGS. 1-12, 13A-13G, 14-16, 17A-17C and/or 18-19 and its corresponding description in the present disclosure is not limited to dies and/or ICs. In some implementations, FIGS. 1-12, 13A-13G, 14-16, 17A-17C and/or 18-19 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object that is coupled to another object may be coupled to at least part of the another object. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. A first component that is “located” in a second component may mean that the first component is “partially located” in the second component or “completely located” in the second component. A first component that is “embedded” in a second component may mean that the first component is “partially embedded” in the second component or “completely embedded” in the second component. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: An integrated device comprising a die substrate; a die interconnection coupled to the die substrate; an encapsulation layer coupled to a side surface of the die substrate and a side surface of the die interconnection; a plurality of pad interconnects coupled to the die interconnection; a passivation layer coupled to the die interconnection; and a plurality of metallization interconnects, wherein one or more metallization interconnects from the plurality of metallization interconnects is coupled to one or more pad interconnects from the plurality of pad interconnects, wherein the plurality of metallization interconnects comprise a first step pad interconnect structure.

Aspect 2: The integrated device of aspect 1, wherein the first step pad interconnect structure comprises a first pad interconnect comprising a first diameter; and a second pad interconnect comprising a second diameter that is different from the first diameter.

Aspect 3: The integrated device of aspect 1, further comprising a solder interconnect coupled to the first step pad interconnect structure.

Aspect 4: The integrated device of aspect 1, wherein the plurality of metallization interconnects comprises a trace metallization interconnect coupled to and touching the first step pad interconnect structure.

Aspect 5: The integrated device of aspect 1, wherein the plurality of metallization interconnects comprises a via metallization interconnect coupled to and touching the first step pad interconnect structure.

Aspect 6: The integrated device of aspect 1, wherein the plurality of metallization interconnects comprises: a first trace metallization interconnect coupled to the first step pad interconnect structure; and a second step pad interconnect structure coupled to the first trace metallization interconnect.

Aspect 7: The integrated device of aspect 1, further comprising a plurality of interconnects located in the encapsulation layer, wherein one or more interconnects from the plurality of interconnects is coupled to one or more metallization interconnects from the plurality of metallization interconnects.

Aspect 8: The integrated device of aspect 1, further comprising a plurality of back side metallization interconnects.

Aspect 9: The integrated device of aspect 8, wherein the plurality of back side metallization interconnects comprise a second step pad interconnect structure.

Aspect 10: The integrated device of aspect 8, further comprising a plurality of through substrate vias located in the die substrate, wherein one or more through substrate vias from the plurality of through substrate vias is coupled to one or more back side metallization interconnects from the plurality of back side metallization interconnects.

Aspect 11: A package comprising a first integrated device comprising: a first die substrate; a first die interconnection coupled to the first die substrate; a first encapsulation layer coupled to a side surface of the first die substrate and a side surface of the first die interconnection; a first plurality of pad interconnects coupled to the first die interconnection; a passivation layer coupled to the first die interconnection; a first plurality of metallization interconnects, wherein one or more metallization interconnects from the first plurality of metallization interconnects is coupled to one or more pad interconnects from the first plurality of pad interconnects, wherein the first plurality of metallization interconnects comprise a first step pad interconnect structure; and a second integrated device coupled to the first integrated device through at least a first plurality of solder interconnects.

Aspect 12: The package of aspect 11, wherein the first step pad interconnect structure comprises: a first pad interconnect comprising a first diameter; and a second pad interconnect comprising a second diameter that is different from the first diameter.

Aspect 13: The package of aspect 11, wherein the second integrated device comprises a second plurality of metallization interconnects, wherein the second plurality of metallization interconnects comprises a second step pad interconnect structure.

Aspect 14: The package of aspect 13, wherein the second plurality of metallization interconnects comprises a plurality of back side metallization interconnects, and wherein the second step pad interconnect structure is part of the plurality of back side metallization interconnects.

Aspect 15: The package of aspect 13, wherein the second step pad interconnect structure comprises: a first pad interconnect comprising a first radius; and a second pad interconnect comprising a second radius that is different from the first radius.

Aspect 16: The package of aspect 11, wherein the first integrated device comprises a first front side and a first back side, and wherein the second integrated device comprises a second front side and a second back side.

Aspect 17: The package of aspect 16, wherein the first front side of the first integrated device is coupled to the second front side of the second integrated device through at least the first plurality of solder interconnects.

Aspect 18: The package of aspect 16, wherein the first front side of the first integrated device is coupled to the second back side of the second integrated device through at least the first plurality of solder interconnects.

Aspect 19: The package of aspect 11, wherein a solder interconnect from the first plurality of solder interconnects is coupled to the first step pad interconnect structure.

Aspect 20: The package of aspect 11, wherein the second integrated device comprises: a second die substrate; a second die interconnection coupled to the second die substrate; a second encapsulation layer coupled to a side surface of the second die substrate and a side surface of the second die interconnection; a second plurality of pad interconnects coupled to the second die interconnection; and a second plurality of metallization interconnects coupled to the second plurality of pad interconnects, wherein the second plurality of metallization interconnects comprises a second step pad interconnect structure.

Aspect 21: The package of aspect 20, wherein a solder interconnect from the first plurality of solder interconnects is coupled to the first step pad interconnect structure and the second step pad interconnect structure.

Aspect 22: The package of aspect 20, further comprising a plurality of interconnects located in the first encapsulation layer, wherein the plurality of interconnects are coupled to the first plurality of metallization interconnects.

Aspect 23: The package of aspect 20, wherein the first integrated device further comprises: a first plurality of through substrate vias located in the first die substrate; and a first plurality of back side metallization interconnects coupled to the first plurality of through substrate vias.

Aspect 24: The package of aspect 23, wherein the first plurality of back side metallization interconnects comprise a second step pad interconnect structure.

Aspect 25: The package of aspect 24, wherein a back side of the first integrated device is coupled to a front side of the second integrated device through the first plurality of solder interconnects, and wherein a solder interconnect from the first plurality of solder interconnects is coupled to the first step pad interconnect structure and the second step pad interconnect structure.

Aspect 26: The package of aspect 20, wherein the first plurality of metallization interconnects comprises a first plurality of step pad interconnect structures comprising a pitch in a range of about 10-50 micrometers, and wherein the second plurality of metallization interconnects comprises a second plurality of step pad interconnect structures comprising a pitch in a range of about 10-50 micrometers.

Aspect 27: The package of aspect 11, wherein the package is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 28: A device comprising a die substrate; a die interconnection coupled to the die substrate; an encapsulation layer coupled to a side surface of the die substrate and a side surface of the die interconnection; a plurality of pad interconnects coupled to the die interconnection; a passivation layer coupled to the die interconnection; and a plurality of metallization interconnects, wherein one or more metallization interconnects from the plurality of metallization interconnects is coupled to one or more pad interconnects from the plurality of pad interconnects, wherein the plurality of metallization interconnects comprise a first step pad interconnect structure.

Aspect 29: The device of aspect 28, wherein the first step pad interconnect structure comprises a first pad interconnect comprising a first diameter; and a second pad interconnect comprising a second diameter that is different from the first diameter.

Aspect 30: The device of aspect 28, further comprising a solder interconnect coupled to the first step pad interconnect structure.

Aspect 31: The device of aspect 28, wherein the plurality of metallization interconnects comprises a trace metallization interconnect coupled to and touching the first step pad interconnect structure.

Aspect 32: The device of aspect 28, wherein the device comprises a die, a passive device, or an interposer.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die substrate;
a die interconnection coupled to the die substrate;
an encapsulation layer coupled to a side surface of the die substrate and a side surface of the die interconnection;
a plurality of pad interconnects coupled to the die interconnection;
a passivation layer coupled to the die interconnection; and
a plurality of metallization interconnects, wherein one or more metallization interconnects from the plurality of metallization interconnects is coupled to one or more pad interconnects from the plurality of pad interconnects, wherein the plurality of metallization interconnects comprise a first step pad interconnect structure.

2. The integrated device of claim 1, wherein the first step pad interconnect structure comprises:
a first pad interconnect comprising a first diameter; and
a second pad interconnect comprising a second diameter that is different from the first diameter.

3. The integrated device of claim 1, further comprising a solder interconnect coupled to the first step pad interconnect structure.

4. The integrated device of claim 1, wherein the plurality of metallization interconnects comprises a trace metallization interconnect coupled to and touching the first step pad interconnect structure.

5. The integrated device of claim 1, wherein the plurality of metallization interconnects comprises a via metallization interconnect coupled to and touching the first step pad interconnect structure.

6. The integrated device of claim 1, wherein the plurality of metallization interconnects comprises:
a first trace metallization interconnect coupled to the first step pad interconnect structure; and
a second step pad interconnect structure coupled to the first trace metallization interconnect.

7. The integrated device of claim 1, further comprising a plurality of interconnects located in the encapsulation layer, wherein one or more interconnects from the plurality of interconnects is coupled to one or more metallization interconnects from the plurality of metallization interconnects.

8. The integrated device of claim 1, further comprising a plurality of back side metallization interconnects.

9. The integrated device of claim 8, wherein the plurality of back side metallization interconnects comprise a second step pad interconnect structure.

10. The integrated device of claim 8, further comprising a plurality of through substrate vias located in the die substrate, wherein one or more through substrate vias from the plurality of through substrate vias is coupled to one or more back side metallization interconnects from the plurality of back side metallization interconnects.

11. A package comprising:
a first integrated device comprising:
a first die substrate;
a first die interconnection coupled to the first die substrate;
a first encapsulation layer coupled to a side surface of the first die substrate and a side surface of the first die interconnection;
a first plurality of pad interconnects coupled to the first die interconnection;
a passivation layer coupled to the first die interconnection;
a first plurality of metallization interconnects, wherein one or more metallization interconnects from the first plurality of metallization interconnects is coupled to one or more pad interconnects from the first plurality of pad interconnects, wherein the first plurality of metallization interconnects comprise a first step pad interconnect structure; and
a second integrated device coupled to the first integrated device through at least a first plurality of solder interconnects.

12. The package of claim 11, wherein the first step pad interconnect structure comprises:
a first pad interconnect comprising a first diameter; and
a second pad interconnect comprising a second diameter that is different from the first diameter.

13. The package of claim 11, wherein the second integrated device comprises a second plurality of metallization interconnects, wherein the second plurality of metallization interconnects comprises a second step pad interconnect structure.

14. The package of claim 13,
wherein the second plurality of metallization interconnects comprises a plurality of back side metallization interconnects, and
wherein the second step pad interconnect structure is part of the plurality of back side metallization interconnects.

15. The package of claim 13, wherein the second step pad interconnect structure comprises:
a first pad interconnect comprising a first radius; and
a second pad interconnect comprising a second radius that is different from the first radius.

16. The package of claim 11,
wherein the first integrated device comprises a first front side and a first back side, and
wherein the second integrated device comprises a second front side and a second back side.

17. The package of claim 16, wherein the first front side of the first integrated device is coupled to the second front side of the second integrated device through at least the first plurality of solder interconnects.

18. The package of claim 16, wherein the first front side of the first integrated device is coupled to the second back side of the second integrated device through at least the first plurality of solder interconnects.

19. The package of claim 11, wherein a solder interconnect from the first plurality of solder interconnects is coupled to the first step pad interconnect structure.

20. The package of claim 11, wherein the second integrated device comprises:
a second die substrate;
a second die interconnection coupled to the second die substrate;
a second encapsulation layer coupled to a side surface of the second die substrate and a side surface of the second die interconnection;
a second plurality of pad interconnects coupled to the second die interconnection; and
a second plurality of metallization interconnects coupled to the second plurality of pad interconnects, wherein the second plurality of metallization interconnects comprises a second step pad interconnect structure.

21. The package of claim 20, wherein a solder interconnect from the first plurality of solder interconnects is coupled to the first step pad interconnect structure and the second step pad interconnect structure.

22. The package of claim 20, further comprising a plurality of interconnects located in the first encapsulation layer, wherein the plurality of interconnects are coupled to the first plurality of metallization interconnects.

23. The package of claim 20, wherein the first integrated device further comprises:
a first plurality of through substrate vias located in the first die substrate; and
a first plurality of back side metallization interconnects coupled to the first plurality of through substrate vias.

24. The package of claim 23, wherein the first plurality of back side metallization interconnects comprise a second step pad interconnect structure.

25. The package of claim 24,
wherein a back side of the first integrated device is coupled to a front side of the second integrated device through the first plurality of solder interconnects, and
wherein a solder interconnect from the first plurality of solder interconnects is coupled to the first step pad interconnect structure and the second step pad interconnect structure.

26. The package of claim 20,
wherein the first plurality of metallization interconnects comprises a first plurality of step pad interconnect structures comprising a pitch in a range of about 10-50 micrometers, and
wherein the second plurality of metallization interconnects comprises a second plurality of step pad interconnect structures comprising a pitch in a range of about 10-50 micrometers.

27. The package of claim 11, wherein the package is part of a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

28. A device comprising:
a die substrate;
a die interconnection coupled to the die substrate;
an encapsulation layer coupled to a side surface of the die substrate and a side surface of the die interconnection;
a plurality of pad interconnects coupled to the die interconnection;
a passivation layer coupled to the die interconnection; and
a plurality of metallization interconnects, wherein one or more metallization interconnects from the plurality of metallization interconnects is coupled to one or more pad interconnects from the plurality of pad interconnects, wherein the plurality of metallization interconnects comprise a first step pad interconnect structure.

29. The device of claim 28, wherein the first step pad interconnect structure comprises:
a first pad interconnect comprising a first diameter; and
a second pad interconnect comprising a second diameter that is different from the first diameter.

30. The device of claim 28, further comprising a solder interconnect coupled to the first step pad interconnect structure.

31. The device of claim 28, wherein the plurality of metallization interconnects comprises a trace metallization interconnect coupled to and touching the first step pad interconnect structure.

32. The device of claim 28, wherein the device comprises a die, a passive device, or an interposer.
